(19) United States
(12) Patent Application Publication
(10) Pub. No.: US 2026/0181873 A1
(43) Pub. Date: Jun. 25, 2026

(54) SEMICONDUCTOR MEMORY DEVICE AND MEMORY SYSTEM INCLUDING THE SAME

(71) Applicant: Samsung Electronics Co., Ltd., Suwon-si (KR)

(72) Inventor: Jeonil LEE, Suwon-si (KR)

(73) Assignee: Samsung Electronics Co., Ltd., Suwon-si (KR)

(21) Appl. No.: 19/337,377

(22) Filed: Sep. 23, 2025

(30) Foreign Application Priority Data
Dec. 19, 2024 (KR) 10-2024-0191337

(51) Int. Cl. H10B 12/00; G11C 11/4091

(52) U.S. Cl. CPC H10B 12/482; G11C 11/4091; H10B 12/50

(57) ABSTRACT

A semiconductor memory device includes memory cells, local bitlines, wordlines, first and second global bitlines, and first and second local bitline multiplexers. Each of the memory cells includes a cell transistor and a cell capacitor. The local bitlines extend in a first direction on the substrate and are connected to the memory cells. The wordlines extend in a third direction on the substrate and are connected to the memory cells. The first global bitlines are on the local bitlines. The second global bitlines are under the local bitlines. The first local bitline multiplexers control electrical connections between the local bitlines and the first global bitlines. The second local bitline multiplexers control electrical connections between the local bitlines and the second global bitlines. First and second memory cells may be accessed simultaneously through the first and second global bitlines and first and second local bitlines.

### CROSS-REFERENCE TO RELATED APPLICATION

This application claims priority under 35 USC § 119 to Korean Patent Application No. 10-2024-0191337, filed on Dec. 19, 2024 in the Korean Intellectual Property Office (KIPO), the contents of which are herein incorporated by reference in their entirety.

### BACKGROUND

### 1. Technical Field

Example embodiments relate generally to semiconductor integrated circuits, and more particularly to three-dimensional (3D) semiconductor memory devices and memory systems including the 3D semiconductor memory devices.

### 2. Description of the Related Art

The demand/desire for the miniaturization, multi-function and/or higher-performance of electronic products causes the demand for higher-capacity semiconductor memory devices. To provide the higher-capacity semiconductor memory devices, an increased degree of integration may be demanded/desired. Since a degree of integration of existing two-dimensional (2D) semiconductor memory devices may mainly be determined by an area occupied by a unit memory cell, the degree of integration of 2D semiconductor memory devices has been increasing, but is still limited. Therefore, three-dimensional (3D) semiconductor memory devices have been proposed to increase a memory capacity by stacking a plurality of memory cells on a substrate in a vertical direction.

### SUMMARY

At least one example embodiment of the present disclosure provides a semiconductor memory device capable of having improved electrical and/or operational characteristics.

At least one example embodiment of the present disclosure provides a memory system including the semiconductor memory device.

According to an example embodiment, a semiconductor memory device may include: a plurality of memory cells on a substrate, the plurality of memory cells being arranged along a first direction, a second direction, and a third direction, the first direction being perpendicular to an upper surface of the substrate, the second direction and the third direction being parallel to the upper surface of the substrate and intersecting each other, each of the plurality of memory cells including a cell transistor and a cell capacitor; a plurality of local bitlines on the substrate, the plurality of local bitlines being connected to the plurality of memory cells, each of the plurality of local bitlines extending in the first direction; a plurality of wordlines on the substrate, the plurality of wordlines being connected to the plurality of memory cells, each of the plurality of wordlines extending in the third direction; a plurality of first global bitlines on the plurality of local bitlines; a plurality of second global bitlines under the plurality of local bitlines; a plurality of first local bitline multiplexers configured to control electrical connections between the plurality of local bitlines and the plurality of first global bitlines; and a plurality of second local bitline multiplexers configured to control electrical connections between the plurality of local bitlines and the plurality of second global bitlines. First memory cells among the plurality of memory cells may be different from second memory cells among the plurality of memory cells. The first memory cells and the second memory cells may be configured to be accessed simultaneously by accessing the first memory cells through the plurality of first global bitlines and first local bitlines among the plurality of local bitlines and by accessing the second memory cells through the plurality of second global bitlines and second local bitlines among the plurality of local bitlines. The first local bitlines among the plurality of local bitlines may be different from the second local bitlines among the plurality of local bitlines.

According to an example embodiment, a semiconductor memory device may include: a first local bitline and a second local bitline on a substrate, the first local bitline and the second local bitline each extending in a first direction, the first direction being perpendicular to an upper surface of the substrate, the first local bitline and the second local bitline being spaced apart from each other in a second direction, the second direction being parallel to the upper surface of the substrate; first memory cells on the substrate, the first memory cells being arranged along the first direction between the first local bitline and the second local bitline, the first memory cells being connected to the first local bitline, each of the first memory cells including a first cell transistor and a first cell capacitor; second memory cells on the substrate, the second memory cells being arranged along the first direction between the first local bitline and the second local bitline, the second memory cells being connected to the second local bitline, each of the second memory cells including a second cell transistor and a second cell capacitor; wordlines on the substrate, the wordlines being connected to the first memory cells and the second memory cells, each of the wordlines extending in a third direction, the third direction being parallel to the upper surface of the substrate and intersecting the second direction; a first global bitline on the first local bitline and the second local bitline; a second global bitline under the first local bitline and the second local bitline; a first local bitline multiplexer and a second local bitline multiplexer on the first memory cells and the second memory cells, respectively, the first local bitline multiplexer being configured to control an electrical connection between the first local bitline and the first global bitline, and the second local bitline multiplexer being configured to control an electrical connection between the second local bitline and the first global bitline; and a third local bitline multiplexer and a fourth local bitline multiplexer under the first memory cells and the second memory cells, respectively, the third local bitline multiplexer being configured to control an electrical connection between the first local bitline and the second global bitline, the fourth local bitline multiplexer being configured to control an electrical connection being between the second local bitline and the second global bitline. A level of a first-first memory cell among the first memory cells may be different from a level of a second-first memory cell among the second memory cells. The first-first memory cell and the second-first memory cell may be configured to be accessed simultaneously by accessing the first-first memory cell through the first global bitline and the first local bitline and by accessing the second-first memory cell through the second global bitline and the second local bitline.

According to an example embodiment, a memory system may include a memory controller; and a semiconductor memory device, wherein the memory controller may be configured to control the semiconductor memory device. The semiconductor memory device may include: a plurality of memory cells on a substrate, the plurality of memory cells being arranged along a first direction, a second direction and a third direction, the first direction being perpendicular to an upper surface of the substrate, the second direction and the third direction being parallel to the upper surface of the substrate and intersecting each other, each of the plurality of memory cells including a cell transistor and a cell capacitor; a plurality of local bitlines on the substrate, the plurality of local bitlines being connected to the plurality of memory cells, each of the plurality of local bitlines extending in the first direction; a plurality of wordlines on the substrate, the plurality of wordlines being connected to the plurality of memory cells, each of the plurality of wordlines extending in the third direction; a plurality of first global bitlines on the plurality of local bitlines; a plurality of second global bitlines under the plurality of local bitlines; a plurality of first local bitline multiplexers configured to control electrical connections between the plurality of local bitlines and the plurality of first global bitlines; and a plurality of second local bitline multiplexers configured to control electrical connections between the plurality of local bitlines and the plurality of second global bitlines. First memory cells among the plurality of memory cells may be different from second memory cells among the plurality of memory cells. The first memory cells and the second memory cells may be configured to be accessed simultaneously by accessing the first memory cells through the plurality of first global bitlines and first local bitlines among the plurality of local bitlines and by accessing the second memory cells through the plurality of second global bitlines and second local bitlines among the plurality of local bitlines. The first local bitlines among the plurality of local bitlines may be different from the second local bitlines among the plurality of local bitlines.

The semiconductor memory device and the memory system according to example embodiments may include the local bitline multiplexers that control the electrical connections between the local bitlines and the global bitlines, and the structures included in the memory cell array may be used as the local bitline multiplexers. In addition, the global bitlines and the local bitline multiplexers may be disposed on both the upper and lower sides of the memory cell array, the structures on the uppermost and lowermost levels of the memory cell array may be used as the local bitline multiplexers, and different memory cells may be accessed simultaneously through the upper and lower global bitlines. Since the memory cells at two different levels may be simultaneously accessed at once, the semiconductor memory device with the high bandwidth may be implemented. Further, the number and size of peripheral circuits such as sense amplifiers and sub-wordline drivers may increase. Accordingly, the semiconductor memory device may have improved electrical characteristics and/or improved reliability.

According to an example embodiments, a method of manufacturing a semiconductor memory device may include forming components of a first layer a substrate. The components of the first layer may include: a plurality of memory cells on a substrate, the plurality of memory cells being arranged along a first direction, a second direction and a third direction, the first direction being perpendicular to an upper surface of the substrate, the second direction and the third direction being parallel to the upper surface of the substrate and intersecting each other, each of the plurality of memory cells including a cell transistor and a cell capacitor; a plurality of local bitlines on the substrate, the plurality of local bitlines being connected to the plurality of memory cells, each of the plurality of local bitlines extending in the first direction; a plurality of wordlines on the substrate, the plurality of wordlines being connected to the plurality of memory cells, each of the plurality of wordlines extending in the third direction; a plurality of first global bitlines on the plurality of local bitlines; a plurality of second global bitlines under the plurality of local bitlines; a plurality of first local bitline multiplexers configured to control electrical connections between the plurality of local bitlines and the plurality of first global bitlines; and a plurality of second local bitline multiplexers configured to control electrical connections between the plurality of local bitlines and the plurality of second global bitlines. The first memory cells among the plurality of memory cells may be different from second memory cells among the plurality of memory cells. The first memory cells and the second memory cells may be configured to be accessed simultaneously by accessing the first memory cells through the plurality of first global bitlines and first local bitlines among the plurality of local bitlines and by accessing the second memory cells through the plurality of second global bitlines and second local bitlines among the plurality of local bitlines. The first local bitlines among the plurality of local bitlines may be different from the second local bitlines among the plurality of local bitlines.

In some embodiments, the plurality of first local bitline multiplexers may on the plurality of memory cells and between the plurality of local bitlines and the plurality of first global bitlines. The plurality of second local bitline multiplexers may be under the plurality of memory cells and between the plurality of local bitlines and the plurality of second global bitlines.

In some embodiments, the first memory cells may be commonly connected to a first wordline among the plurality of wordlines. The second memory cells may be commonly connected to a second wordline among the plurality of wordlines. The first wordline and the second wordline may be different from each other.

In some embodiments, the method may further include forming a second layer on a first surface of the first layer, wherein the second layer may include a first peripheral circuit including first transistors, the forming of the second layer on the first surface of the first layer may include forming first connecting lines that electrically connect the first transistors of the first peripheral circuit to the plurality of first global bitlines in the first layer.

In some embodiments, the method may further include forming a third layer on a second surface of the first layer, wherein the second surface of the first layer may be opposite the first surface of the first layer, the third layer may include a second peripheral circuit including second transistors, and the forming of the third layer on the second surface of the first layer may include forming second connecting lines that electrically connect the second transistors of the second peripheral circuit to the plurality of second global bitlines in the first layer.

### BRIEF DESCRIPTION OF THE DRAWINGS

Illustrative, non-limiting example embodiments will be more clearly understood from the following detailed description taken in conjunction with the accompanying drawings.

FIG. 1 is a perspective view of a semiconductor memory device according to example embodiments.

FIG. 2 is a circuit diagram illustrating an example of a semiconductor memory device of FIG. 1.

FIG. 3 is a diagram for describing an operation of a semiconductor memory device of FIG. 1.

FIG. 4 is a plan view for describing a semiconductor memory device according to example embodiments.

FIGS. 5, 6, 7, 8 and 9 are cross-sectional views for describing a semiconductor memory device of FIG. 4.

FIG. 10 is a perspective view of a semiconductor memory device according to example embodiments.

FIG. 11 is a perspective view of a semiconductor memory device according to example embodiments.

FIG. 12 is a circuit diagram illustrating an example of a semiconductor memory device of FIGS. 10 and 11.

FIGS. 13A, 13B, 13C and 13D are cross-sectional views for describing a method of manufacturing a semiconductor memory device according to example embodiments.

FIGS. 14 and 15 are perspective views of a semiconductor memory device according to example embodiments.

FIG. 16 is a block diagram illustrating a semiconductor memory device according to example embodiments.

FIG. 17 is a block diagram illustrating a memory system according to example embodiments.

### DETAILED DESCRIPTION OF THE EMBODIMENTS

Various example embodiments will be described more fully with reference to the accompanying drawings, in which embodiments are shown. The present disclosure may, however, be embodied in many different forms and should not be construed as limited to the embodiments set forth herein. Like reference numerals refer to like elements throughout this application.

Hereinafter, in the specification (and not necessarily in the claims), a vertical direction that is substantially perpendicular to an upper surface of a substrate may be referred to as a first direction D1, and two intersecting directions among horizontal directions that are substantially parallel to the upper surface of the substrate may be referred to as second and third directions D2 and D3, respectively. For example, the second and third directions D2 and D3 may be substantially perpendicular to each other. Each of the first, second and third directions D1, D2 and D3 may include not only a direction shown in the drawings but also a direction inverse thereto.

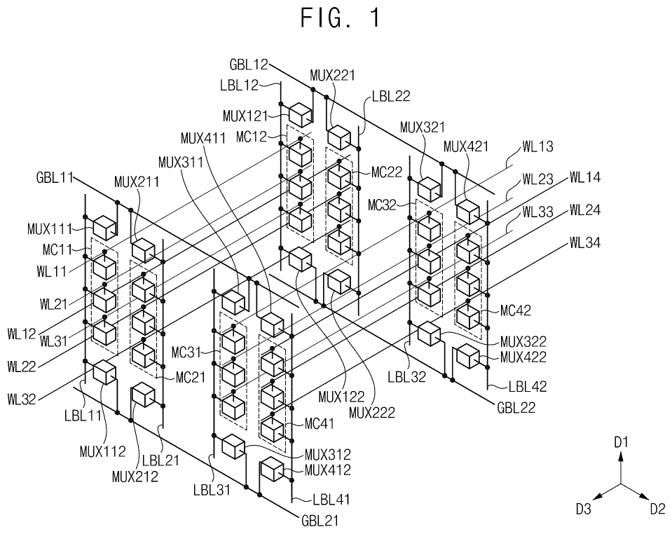

FIG. 1 is a perspective view of a semiconductor memory device according to example embodiments.

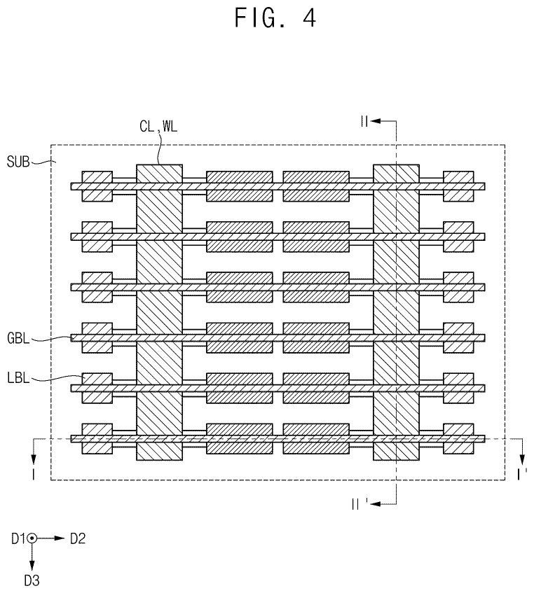

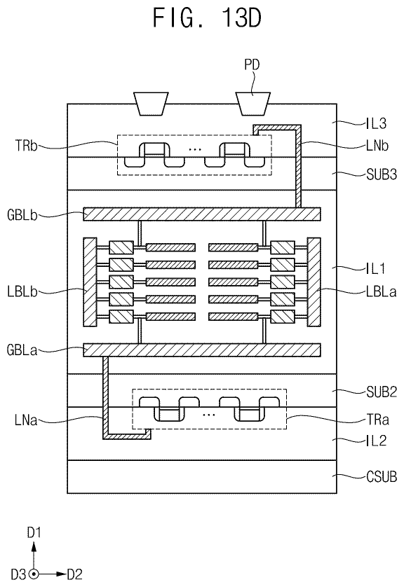

Referring to FIG. 1, a portion of a memory cell array of a semiconductor memory device is illustrated. For example, the memory cell array (or the portion thereof) may be formed, disposed and/or arranged on a substrate (e.g., a substrate SUB in FIG. 4 and/or a first substrate SUB1 in FIG. 13A).

The semiconductor memory device includes a plurality of memory cells MC11, MC21, MC31, MC41, MC12, MC22, MC32 and MC42, a plurality of local bitlines LBL11, LBL21, LBL31, LBL41, LBL12, LBL22, LBL32 and LBL42, a plurality of wordlines WL11, WL21, WL31, WL12, WL22, WL32, WL13, WL23, WL33, WL14, WL24 and WL34, a plurality of first global bitlines GBL11 and GBL12, a plurality of second global bitlines GBL21 and GBL22, a plurality of first local bitline multiplexers MUX111, MUX211, MUX311, MUX411, MUX121, MUX221, MUX321 and MUX421, and a plurality of second local bitline multiplexers MUX112, MUX212, MUX312, MUX412, MUX122, MUX222, MUX322 and MUX422.

The plurality of memory cells MC11, MC21, MC31, MC41, MC12, MC22, MC32 and MC42 are disposed on the substrate, and are arranged along the first, second and third directions D1, D2 and D3. Unlike a two-dimensional (2D) semiconductor memory device in which memory cells are arranged only along the second and third directions D2 and D3, the semiconductor memory device according to example embodiments may be a three-dimensional (3D) semiconductor memory device in which the plurality of memory cells MC11, MC21, MC31, MC41, MC12, MC22, MC32 and MC42 are arranged not only along the second and third directions D2 and D3 but also along the first direction D1.

The plurality of local bitlines LBL11, LBL21, LBL31, LBL41, LBL12, LBL22, LBL32 and LBL42 are disposed on the substrate, and are electrically connected to the plurality of memory cells MC11, MC21, MC31, MC41, MC12, MC22, MC32 and MC42. Each of the plurality of local bitlines LBL11, LBL21, LBL31, LBL41, LBL12, LBL22, LBL32 and LBL42 extends in the first direction D1. The plurality of local bitlines LBL11, LBL21, LBL31, LBL41, LBL12, LBL22, LBL32 and LBL42 may be spaced apart from each other in the second and third directions D2 and D3.

In some example embodiments, some memory cells may be disposed between two local bitlines that are arranged adjacently along the second direction D2. Memory cells that are arranged adjacently along the first direction D1 in which each local bitline extends may be electrically connected to the same local bitline. For example, memory cells that are arranged along the first direction D1 may form one cell string, and each cell string and the memory cells included therein may be electrically connected to one local bitline.

For example, the memory cells MC11 and MC21 may be disposed between the local bitlines LBL11 and LBL21 that are adjacent to each other in the second direction D2. Among the memory cells MC11 and MC21, the memory cells MC11 that are arranged along the first direction D1 may be electrically connected to the same local bitline (e.g., the local bitline LBL11), and the memory cells MC21 that are arranged along the first direction D1 may be electrically connected to the same local bitline (e.g., the local bitline LBL21).

For example, the memory cells MC31 and MC41 may be disposed between the local bitlines LBL31 and LBL41 that are adjacent to each other in the second direction D2. Among the memory cells MC31 and MC41, the memory cells MC31 that are arranged along the first direction D1 may be electrically connected to the same local bitline (e.g., the local bitline LBL31), and the memory cells MC41 that are arranged along the first direction D1 may be electrically connected to the same local bitline e.g., the local bitline LBL41.

Similarly, the memory cells MC12 and MC22 may be disposed between the local bitlines LBL12 and LBL22, the memory cells MC12 may be electrically connected to the local bitline LBL12, and the memory cells MC22 may be electrically connected to the local bitline LBL22. The memory cells MC32 and MC42 may be disposed between the local bitlines LBL32 and LBL42, the memory cells MC32 may be electrically connected to the local bitline LBL32, and the memory cells MC42 may be electrically connected to the local bitline LBL42.

The plurality of wordlines WL11, WL21, WL31, WL12, WL22, WL32, WL13, WL23, WL33, WL14, WL24 and WL34 are disposed on the substrate, and are electrically connected to the plurality of memory cells MC11, MC21, MC31, MC41, MC12, MC22, MC32 and MC42. Each of the plurality of wordlines WL11, WL21, WL31, WL12, WL22, WL32, WL13, WL23, WL33, WL14, WL24 and WL34 extends in the third direction D3. The plurality of wordlines WL11, WL21, WL31, WL12, WL22, WL32, WL13, WL23, WL33, WL14, WL24 and WL34 may be spaced apart from each other in the first and second directions D1 and D2.

In some example embodiments, the plurality of memory cells MC11, MC21, MC31, MC41, MC12, MC22, MC32 and MC42 may be disposed at a plurality of levels in the first direction D1, and memory cells that are disposed at the same level and arranged adjacently along the third direction D3 along which each wordline extends may be electrically connected to the same wordline. For example, memory cells that are arranged along the third direction D3 at the same level may form one cell column, and each cell column and the memory cells included therein may be electrically connected to one wordline.

For example, among the memory cells MC11 and the memory cells MC12 that are adjacent to each other in the third direction D3, memory cells at the same level may be electrically connected to the same wordline among the wordlines WL11, WL21 and WL31. For example, among the memory cells MC11 and MC12, memory cells at the uppermost level (or top level) may be electrically connected to the wordline WL11, memory cells at the middle level may be electrically connected to the wordline WL21, and memory cells at the lowermost level (or bottom level) may be electrically connected to the wordline WL31.

For example, among the memory cells MC21 and the memory cells MC22 that are adjacent to each other in the third direction D3, memory cells at the same level may be electrically connected to the same wordline among the wordlines WL12, WL22 and WL32. For example, among the memory cells MC21 and MC22, memory cells at the uppermost level may be electrically connected to the wordline WL12, memory cells at the middle level may be electrically connected to the wordline WL22, memory cells at the lowermost level may be electrically connected to the wordline WL32.

Similarly, among the memory cells MC31 and the memory cells MC32 that are adjacent to each other in the third direction D3, memory cells at the same level may be electrically connected to the same wordline among the wordlines WL13, WL23 and WL33. Among the memory cells MC41 and the memory cells MC42 that are adjacent to each other in the third direction D3, memory cells at the same level may be electrically connected to the same wordline among the wordlines WL14, WL24 and WL34.

The plurality of first global bitlines GBL11 and GBL12 are disposed on the plurality of local bitlines LBL11, LBL21, LBL31, LBL41, LBL12, LBL22, LBL32 and LBL42. For example, each of the plurality of first global bitlines GBL11 and GBL12 may extend in the second direction D2.

The plurality of second global bitlines GBL21 and GBL22 are disposed under the plurality of local bitlines LBL11, LBL21, LBL31, LBL41, LBL12, LBL22, LBL32 and LBL42. For example, each of the plurality of second global bitlines GBL21 and GBL22 may extend in the second direction D2.

Each of the plurality of first and second global bitlines GBL11, GBL12, GBL21 and GBL22 are selectively connected to one of plurality of local bitlines LBL11, LBL21, LBL31, LBL41, LBL12, LBL22, LBL32 and LBL42. For example, the first global bitline GBL11 that is disposed on the local bitlines LBL11, LBL21, LBL31 and LBL41 may be selectively connected to one of the local bitlines LBL11, LBL21, LBL31 and LBL41, and the first global bitline GBL12 that is disposed on the local bitlines LBL12, LBL22, LBL32 and LBL42 may be selectively connected to one of the local bitlines LBL12, LBL22, LBL32 and LBL42. Similarly, the second global bitline GBL21 that is disposed under the local bitlines LBL11, LBL21, LBL31 and LBL41 may be selectively connected to one of the local bitlines LBL11, LBL21, LBL31 and LBL41, and the second global bitline GBL22 that is disposed under the local bitlines LBL12, LBL22, LBL32 and LBL42 may be selectively connected to the local bitlines LBL12, LBL22, LBL32 and LBL42.

The plurality of first local bitline multiplexers MUX111, MUX211, MUX311, MUX411, MUX121, MUX221, MUX321 and MUX421 control electrical connections between the plurality of local bitlines LBL11, LBL21, LBL31, LBL41, LBL12, LBL22, LBL32 and LBL42 and the plurality of first global bitlines GBL11 and GBL12. For example, the plurality of first local bitline multiplexers MUX111, MUX211, MUX311, MUX411, MUX121, MUX221, MUX321 and MUX421 may be disposed on the plurality of memory cells MC11, MC21, MC31, MC41, MC12, MC22, MC32 and MC42, and may be disposed between the plurality of local bitlines LBL11, LBL21, LBL31, LBL41, LBL12, LBL22, LBL32 and LBL42 and the plurality of first global bitlines GBL11 and GBL12.

For example, the first local bitline multiplexer MUX111 may control the electrical connection between the local bitline LBL11 and the first global bitline GBL11, the first local bitline multiplexer MUX211 may control the electrical connection between the local bitline LBL21 and the first global bitline GBL11, the first local bitline multiplexer MUX311 may control the electrical connection between the local bitline LBL31 and the first global bitline GBL11, and the first local bitline multiplexer MUX411 may control the electrical connection between the local bitline LBL41 and the first global bitline GBL11. Similarly, the first local bitline multiplexer MUX121 may control the electrical connection between the local bitline LBL12 and the first global bitline GBL12, the first local bitline multiplexer MUX221 may control the electrical connection between the local bitline LBL22 and the first global bitline GBL12, the first local bitline multiplexer MUX321 may control the electrical connection between the local bitline LBL32 and the first global bitline GBL12, and the first local bitline multiplexer MUX421 may control the electrical connection between the local bitline LBL42 and the first global bitline GBL12.

The plurality of second local bitline multiplexers MUX112, MUX212, MUX312, MUX412, MUX122, MUX222, MUX322 and MUX422 control electrical connections between the plurality of local bitlines LBL11, LBL21, LBL31, LBL41, LBL12, LBL22, LBL32 and LBL42 and the plurality of second global bitlines GBL21 and GBL22. For example, the plurality of second local bitline multiplexers MUX112, MUX212, MUX312, MUX412, MUX122, MUX222, MUX322 and MUX422 may be disposed under the plurality of memory cells MC11, MC21, MC31, MC41, MC12, MC22, MC32 and MC42, and may be disposed between the plurality of local bitlines LBL11, LBL21, LBL31, LBL41, LBL12, LBL22, LBL32 and LBL42 and the plurality of second global bitlines GBL21 and GBL22.

For example, the second local bitline multiplexer MUX112 may control the electrical connection between the local bitline LBL11 and the second global bitline GBL21, the second local bitline multiplexer MUX212 may control the electrical connection between the local bitline LBL21 and the second global bitline GBL21, the second local bitline multiplexer MUX312 may control the electrical connection between the local bitline LBL31 and the second global bitline GBL21, and the second local bitline multiplexer MUX412 may control the electrical connection between the local bitline LBL41 and the second global bitline GBL21. Similarly, the second local bitline multiplexer MUX122 may control the electrical connection between the local bitline LBL12 and the second global bitline GBL22, the second local bitline multiplexer MUX222 may control the electrical connection between the local bitline LBL22 and the second global bitline GBL22, the second local bitline multiplexer MUX322 may control the electrical connection between the local bitline LBL32 and the second global bitline GBL22, and the second local bitline multiplexer MUX422 may control the electrical connection between the local bitline LBL42 and the second global bitline GBL22.

In some example embodiments, one cell string, one first local bitline multiplexer and one second local bitline multiplexer may be connected to one local bitline. Thus, the number of the local bitlines, the number of the first local bitline multiplexers and the number of the second local bitline multiplexers may be equal to each other.

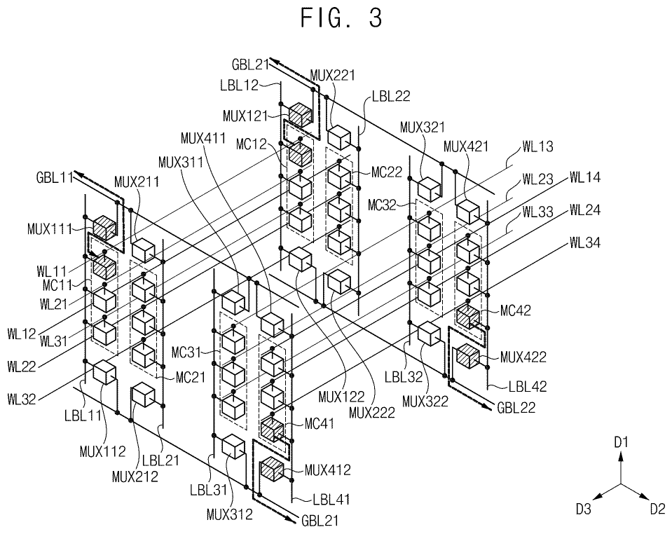

In some example embodiments, memory cells at two different levels may be simultaneously accessed at once through the plurality of first global bitlines GBL11 and GBL12 and the plurality of second global bitlines GBL21 and GBL22, which will be described with reference to FIG. 3.

Although FIG. 1 illustrates an example of the semiconductor memory device that includes specific numbers of memory cells, local bitlines, wordlines, global bitlines and local bitline multiplexers, example embodiments are not limited thereto.

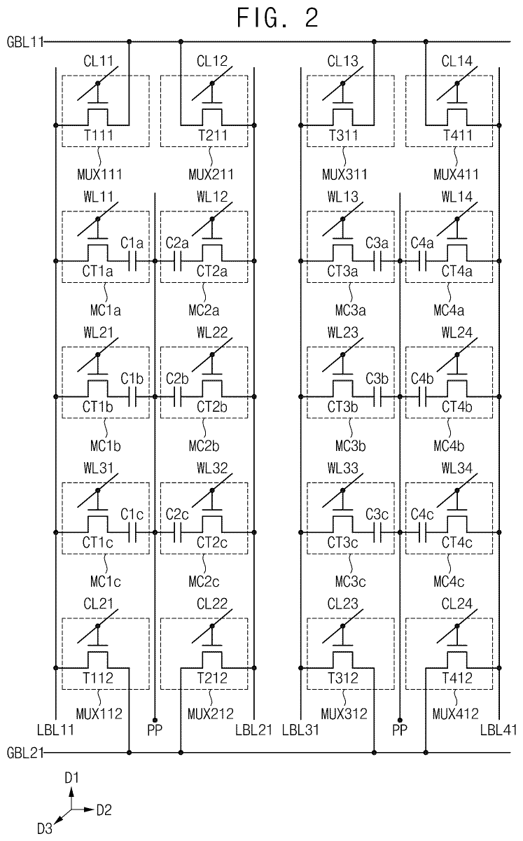

FIG. 2 is a circuit diagram illustrating an example of a semiconductor memory device of FIG. 1.

Referring to FIG. 2, an example of components (or elements) that are connected to the local bitlines LBL11, LBL21, LBL31 and LBL41, the first global bitline GBL11 and the second global bitline GBL21 in the semiconductor memory device of FIG. 1 is illustrated. The descriptions repeated with or overlapping with descriptions of FIG. 1 will be omitted in the interest of brevity.

Each of memory cells MC1a, MC1b, MC1c, MC2a, MC2b, MC2c, MC3a, MC3b, MC3c, MC4a, MC4b and MC4c may include one of cell transistors CT1a, CT1b, CT1c, CT2a, CT2b, CT2c, CT3a, CT3b, CT3c, CT4a, CT4b and CT4c and one of cell capacitors C1a, C1b, C1c, C2a, C2b, C2c, C3a, C3b, C3c, C4a, C4b and C4c, and may be connected to one of the local bitlines LBL11, LBL21, LBL31 and LBL41 and one of the wordlines WL11, WL21, WL31, WL12, WL22, WL32, WL13, WL23, WL33, WL14, WL24 and WL34. In other words, the semiconductor memory device may be a dynamic random access memory (DRAM) device, and each memory cell may be a DRAM cell with a 1T-1C structure including one cell transistor and one cell capacitor.

Each of the cell transistors CT1a, CT1b, CT1c, CT2a, CT2b, CT2c, CT3a, CT3b, CT3c, CT4a, CT4b and CT4c may include a gate electrode that is connected to one of the wordlines WL11, WL21, WL31, WL12, WL22, WL32, WL13, WL23, WL33, WL14, WL24 and WL34, a first source/drain layer that is connected to one of the local bitlines LBL11, LBL21, LBL31 and LBL41, and a second source/drain layer that is connected to one of the cell capacitors C1a, C1b, C1c, C2a, C2b, C2c, C3a, C3b, C3c, C4a, C4b and C4c. The cell capacitors C1a, C1b, C1c, C2a, C2b, C2c, C3a, C3b, C3c, C4a, C4b and C4c may be commonly connected to a plate (or plate electrode) PP.

For example, the memory cell MC1a may include the cell transistor CT1a and the cell capacitor C1a, the cell transistor CT1a may have a gate electrode connected to the wordline WL11 and may be connected between the local bitline LBL11 and the cell capacitor C1a, and the cell capacitor C1a may be connected between the cell transistor CT1a and the plate PP. Similarly, the memory cell MC1b may include the cell transistor CT1b and the cell capacitor C1b, and may be connected to the wordline WL21 and the local bitline LBL11. The memory cell MC1c may include the cell transistor CT1c and the cell capacitor C1c, and may be connected to the wordline WL31 and the local bitline LBL11. The memory cells MC1a, MC1b and MC1c may correspond to the memory cells MC11 in FIG. 1.

Similarly, the memory cells MC2a, MC2b and MC2c may include the cell transistors CT2a, CT2b and CT2c and the cell capacitors C2a, C2b and C2c, may be connected to the wordlines WL12, WL22 and WL32 and the local bitline LBL21, and may correspond to the memory cells MC21 in FIG. 1. The memory cells MC3a, MC3b and MC3c may include the cell transistors CT3a, CT3b and CT3c and the cell capacitors C3a, C3b and C3c, may be connected to the wordlines WL13, WL23 and WL33 and the local bitline LBL31, and may correspond to the memory cells MC31 in FIG. 1. The memory cells MC4a, MC4b and MC4c may include the cell transistors CT4a, CT4b and CT4c and the cell capacitors C4a, C4b and C4c, may be connected to the wordlines WL14, WL24 and WL34 and the local bitline LBL41, and may correspond to the memory cells MC41 in FIG. 1.

Each of the first local bitline multiplexers MUX111, MUX211, MUX311 and MUX411 may include one of first selection transistors T111, T211, T311 and T411. The semiconductor memory device may further include first control lines CL11, CL12, CL13 and CL14 that control turning on and off of the first local bitline multiplexers MUX111, MUX211, MUX311 and MUX411. Each of the first control lines CL11, CL12, CL13 and CL14 may extend in the third direction D3.

For example, the first local bitline multiplexer MUX111 may include the first selection transistor T111. The first selection transistor T111 may be connected between the local bitline LBL11 and the first global bitline GBL11, and may have a gate electrode connected to the first control line CL11.

Similarly, the first local bitline multiplexer MUX211 may include the first selection transistor T211 that is connected between the local bitline LBL21 and the first global bitline GBL11 and has a gate electrode connected to the first control line CL12. The first local bitline multiplexer MUX311 may include the first selection transistor T311 that is connected between the local bitline LBL31 and the first global bitline GBL11 and has a gate electrode connected to the first control line CL13. The first local bitline multiplexer MUX411 may include the first selection transistor T411 that is connected between the local bitline LBL41 and the first global bitline GBL11 and has a gate electrode connected to the first control line CL14.

Each of the second local bitline multiplexers MUX112, MUX212, MUX312 and MUX412 may include one of second selection transistors T112, T212, T312 and T412. The semiconductor memory device may further include second control lines CL21, CL22, CL23 and CL24 that control turning on and off of the second local bitline multiplexers MUX112, MUX212, MUX312 and MUX412. Each of the second control lines CL21, CL22, CL23 and CL24 may extend in the third direction D3.

For example, the second local bitline multiplexer MUX112 may include the second select transistor T112. The second select transistor T112 may be connected between the local bitline LBL11 and the second global bitline GBL21, and may have a gate electrode connected to the second control line CL21.

Similarly, the second local bitline multiplexer MUX212 may include the second selection transistor T212 that is connected between the local bitline LBL21 and the second global bitline GBL21 and has a gate electrode connected to the second control line CL22. The second local bitline multiplexer MUX312 may include the second selection transistor T312 that is connected between the local bitline LBL31 and the second global bitline GBL21 and has a gate electrode connected to the second control line CL23. The second local bitline multiplexer MUX412 may include the second selection transistor T412 that is connected between the local bitline LBL41 and the second global bitline GBL21 and has a gate electrode connected to the second control line CL24.

In some example embodiments, the first and second selection transistors T111, T211, T311, T411, T112, T212, T312 and T412 may be n-type metal oxide semiconductor (NMOS) transistors, but example embodiments are not limited thereto.

In some example embodiments, the first and second selection transistors T111, T211, T311, T411, T112, T212, T312 and T412 that are included in the first and second local bitline multiplexers MUX111, MUX211, MUX311, MUX411, MUX112, MUX212, MUX312, MUX412, the first and second control lines CL11, CL12, CL13, CL14, CL21, CL22, CL23 and CL24 that are connected to the first and second selection transistors T111, T211, T311, T411, T112, T212, T312 and T412, the cell transistors CT1a, CT1b, CT1c, CT2a, CT2b, CT2c, CT3a, CT3b, CT3c, CT4a, CT4b and CT4c that are included in the memory cells MC1a, MC1b, MC1c, MC2a, MC2b, MC2c, MC3a, MC3b, MC3c, MC4a, MC4b and MC4c, and the wordlines WL11, WL21, WL31, WL12, WL22, WL32, WL13, WL23, WL33, WL14, WL24 and WL34 that are connected to the cell transistors CT1a, CT1b, CT1c, CT2a, CT2b, CT2c, CT3a, CT3b, CT3c, CT4a, CT4b and CT4c may be formed or fabricated through the same manufacturing process.

For example, the first and second control lines CL11, CL12, CL13, CL14, CL21, CL22, CL23 and CL24 and the wordlines WL11, WL21, WL31, WL12, WL22, WL32, WL13, WL23, WL33, WL14, WL24 and WL34 may include a plurality of structures formed through the same manufacturing process. Among the plurality of structures, the uppermost structures (e.g., structures at the uppermost level) may be used as the first control lines CL11, CL12, CL13 and CL14, the lowermost structures (e.g., structures at the lowermost level) may be used as the second control lines CL21, CL22, CL23 and CL24, and the remaining structures other than the uppermost and lowermost structures may be used as the wordlines WL11, WL21, WL31, WL12, WL22, WL32, WL13, WL23, WL33, WL14, WL24 and WL34.

Therefore, the first control line CL11 may be disposed on the wordlines WL11, WL21 and WL31, the first control line CL12 may be disposed on the wordlines WL12, WL22 and WL32, the first control line CL13 may be disposed on the wordlines WL13, WL23 and WL33, and the first control line CL14 may be disposed on the wordlines WL14, WL24 and WL34. In addition, the second control line CL21 may be disposed under the wordlines WL11, WL21 and WL31, the second control line CL22 may be disposed under the wordlines WL12, WL22 and WL32, the second control line CL23 may be disposed under the wordlines WL13, WL23 and WL33, and the second control line CL24 may be disposed under the wordlines WL14, WL24 and WL34.

For example, a plurality of transistors may be formed to be connected to the plurality of structures through the same manufacturing process. Among the plurality of transistors, the uppermost transistors that are connected to the uppermost structures may be used as the first selection transistors T111, T211, T311 and T411, the lowermost transistors that are connected to the lowermost structures may be used as the second selection transistors T112, T212, T312 and T412, and the remaining transistors other than the uppermost and lowermost transistors that are connected to the remaining structures other than the uppermost and lowermost structures may be used as the cell transistors CT1a, CT1b, CT1c, CT2a, CT2b, CT2c, CT3a, CT3b, CT3c, CT4a, CT4b and CT4c.

As described above, the global bitlines may be disposed on both the upper and lower sides of the memory cell array included in the 3D semiconductor memory device (e.g., the upper and lower GBL structure or two side GBL structure may be implemented), and the structures at the uppermost and lowermost levels of the memory cell array included in the 3D semiconductor memory device may be used as the local bitline multiplexers rather than the memory cells. Accordingly, the semiconductor memory device may have improved electrical characteristics and improved reliability.

Although not illustrated in detail, components that are connected to the local bitlines LBL12, LBL22, LBL32 and LBL42, the first global bitline GBL12 and the second global bitline GBL22, e.g., the memory cells MC12, MC22, MC32 and MC42, the first local bitline multiplexers MUX121, MUX221, MUX321 and MUX421 and the second local bitline multiplexers MUX122, MUX222, MUX322 and MUX422 may also be implemented similarly to those described with reference to FIG. 2. Therefore, first selection transistors that are included in the plurality of first local bitline multiplexers MUX111, MUX211, MUX311, MUX411, MUX121, MUX221, MUX321 and MUX421 and adjacent to each other in the third direction D3 may be connected to the same first control line, and second selection transistors that are included in the plurality of second local bitline multiplexers MUX112, MUX212, MUX312, MUX412, MUX122, MUX222, MUX322 and MUX422 and adjacent to each other in the third direction D3 may be connected to the same second control line.

In some example embodiments, although not illustrated in FIG. 2, the semiconductor memory device may be implemented with a wordline merging structure in which wordlines (e.g., the wordlines WL11 and WL12) connected to memory cells (e.g., the memory cells MC1a and MC2a) that are disposed at the same level and adjacent to each other in the second direction D2 are merged into one wordline. In some example embodiments, although not illustrated in FIG. 2, the semiconductor memory device may be implemented such that the first local bitline multiplexers (e.g., MUX111, MUX211, MUX311 and MUX411) or the second local bitline multiplexers (e.g., MUX121, MUX221, MUX321 and MUX421) that are adjacent to each other in the second direction D2 are connected to different global bitlines rather than the same global bitline (e.g., GBL11 or GBL21).

FIG. 3 is a diagram for describing an operation of a semiconductor memory device of FIG. 1.

Referring to FIG. 3, an example of an access operation for some of the plurality of memory cells MC11, MC21, MC31, MC41, MC12, MC22, MC32 and MC42 is illustrated. For example, the access operation may include a write operation for storing data in memory cells, a read operation for reading data from memory cells, etc.

In some example embodiments, hatched memory cells among the memory cells MC11 and MC21 may be accessed through the first global bitlines GBL11 and GBL12, which are disposed on the upper side, and the local bitlines LBL11 and LBL12.

For example, when the wordline WL11 is enabled or activated, the hatched memory cells among the memory cells MC11 and MC21 that are disposed at the same level (e.g., the uppermost level) and are commonly connected to the wordline WL11 may be accessed through the wordline WL11. In addition, when the first local bitline multiplexers MUX111 and MUX121 are turned on, the first global bitlines GBL11 and GBL12 and the local bitlines LBL11 and LBL12 may be electrically connected to each other, and the hatched memory cells among the memory cells MC11 and MC21 may be accessed through the first global bitlines GBL11 and GBL12 and the local bitlines LBL11 and LBL12.

In some example embodiments, hatched memory cells among the memory cells MC41 and MC42 may be accessed through the second global bitlines GBL21 and GBL22, which are disposed on the lower side, and the local bitlines LBL41 and LBL42.

For example, when the wordline WL34 is enabled or activated, the hatched memory cells among the memory cells MC41 and MC42 that are disposed at the same level (e.g., the lowermost level) and are commonly connected to the wordline WL34 may be accessed through the wordline WL34. In addition, when the second local bitline multiplexers MUX412 and MUX422 are turned on, the second global bitlines GBL21 and GBL22 and the local bitlines LBL41 and LBL42 may be electrically connected to each other, and the hatched memory cells among the memory cells MC41 and MC42 can be accessed through the second global bitlines GBL21 and GBL22 and the local bitlines LBL41 and LBL42.

In some example embodiments, some of the plurality of memory cells MC11, MC21, MC31, MC41, MC12, MC22, MC32 and MC42 may be accessed simultaneously or concurrently through the first global bitlines GBL11 and GBL12 and the second global bitlines GBL21 and GBL22.

For example, the hatched memory cells among the memory cells MC11 and MC21 that are accessed through the first global bitlines GBL11 and GBL12 and the local bitlines LBL11 and LBL12 may be accessed simultaneously with the hatched memory cells among the memory cells MC41 and MC42 that are accessed through the second global bitlines GBL21 and GBL22 and the local bitlines LBL41 and LBL42.

In some example embodiments, the memory cells that are accessed simultaneously through the first global bitlines GBL11 and GBL12 and the second global bitlines GBL21 and GBL22 may be connected to different local bitlines, may be disposed at different levels, and may be connected to different wordlines.

For example, the hatched memory cells among the memory cells MC11 and MC21 and the hatched memory cells among the memory cells MC41 and MC42 may be connected to different local bitlines LBL11, LBL12, LBL41 and LBL42, may be disposed at different levels (e.g., the uppermost level and the lowermost level), and may be connected to different wordlines WL11 and WL34.

In other words, memory cells (e.g., memory cells connected to the wordline WL31 among the memory cells MC11 and MC21) that are disposed at different level, are connected to different wordlines, and are connected to the same local bitlines may not be accessed simultaneously with the hatched memory cells among the memory cells MC11 and MC21. In addition, memory cells (e.g., memory cells connected to the wordline WL12 among the memory cells MC21 and MC22) that are disposed at the same level and are connected to different local bitlines may not be accessed simultaneously with the hatched memory cells among the memory cells MC11 and MC21.

In some example embodiments, the hatched memory cells among the memory cells MC11 and MC21 accessed through the first global bitlines GBL11 and GBL12 may be adjacent (e.g., closer) to the first global bitlines GBL11 and GBL12 than the hatched memory cells among the memory cells MC41 and MC42 accessed through the second global bitlines GBL21 and GBL22, and the wordline WL11 connected to the hatched memory cells among the memory cells MC11 and MC21 may be adjacent (e.g., closer) to the first global bitlines GBL11 and GBL12 than the wordline WL34 connected to the hatched memory cells among the memory cells MC41 and MC42. Similarly, the hatched memory cells among the memory cells MC41 and MC42 accessed through the second global bitlines GBL21 and GBL22 may be adjacent (e.g., closer) to the second global bitlines GBL21 and GBL22 than the hatched memory cells among the memory cells MC11 and MC21 accessed through the first global bitlines GBL11 and GBL12, and the wordline WL34 connected to the hatched memory cells among the memory cells MC41 and MC42 may be adjacent (e.g., closer) to the second global bitlines GBL21 and GBL22 than the wordline WL11 connected to the hatched memory cells among the memory cells MC11 and MC21. In other words, the hatched memory cells among the memory cells MC11 and MC21 and the wordline WL11 connected thereto may be disposed at a relatively upper level, and the hatched memory cells among the memory cells MC41 and MC42 and the wordline WL34 connected thereto may be disposed at a relatively lower level.

In FIG. 3, the turned-on local bitline multiplexers MUX111, MUX121, MUX412 and MUX422 are illustrated with hatching, and the access operations for the hatched memory cells among the memory cells MC11, MC21, MC41 and MC42 are illustrated with thick dotted lines. Directions of arrows on the thick dotted lines may be changed depending on the type of access operation (e.g., write operation, read operation, etc.).

The semiconductor memory device according to example embodiments may include the local bitline multiplexers that control the electrical connections between the local bitlines and the global bitlines, and the structures included in the memory cell array may be used as the local bitline multiplexers. For example, the local bitline and the global bitline may be selectively connected and disconnected using the local bitline multiplexer, and thus the capacitance (e.g., CBL) of the bitline may be reduced and the sensing margin may increase.

In addition, in the semiconductor memory device according to example embodiments, the global bitlines and the local bitline multiplexers may be disposed on both the upper and lower sides of the memory cell array, the structures on the uppermost and lowermost levels of the memory cell array may be used as the local bitline multiplexers, and different memory cells may be accessed simultaneously through the upper and lower global bitlines. Since the memory cells at two different levels may be simultaneously accessed at once, the semiconductor memory device with the high bandwidth may be implemented. Further, the number and size of peripheral circuits such as sense amplifiers and sub-wordline drivers may increase. Accordingly, the semiconductor memory device may have improved electrical characteristics and improved reliability.

FIG. 4 is a plan view for describing a semiconductor memory device according to example embodiments.

Referring to FIG. 4, a portion of the memory cell array of the semiconductor memory device and/or a portion of a sub-cell array included in the memory cell array is illustrated.

The semiconductor memory device may include local bitlines LBL, global bitlines GBL, wordlines WL, control lines CL, memory cells and local bitline multiplexers that are formed or disposed on a substrate SUB. Although not illustrated in detail, the semiconductor memory device may further include an insulating interlayer that is disposed on the substrate SUB and covers the above structures.

The substrate SUB may include a semiconductor material, e.g., silicon, germanium, silicon-germanium, etc., or a III-V group compound semiconductor, such as GaP, GaAs, GaSb, etc. In some example embodiments, the substrate SUB may be a silicon-on-insulator (SOI) substrate or a germanium-on-insulator (GOI) substrate. As will be described with reference to FIGS. 13A, 13B, 13C and 13D, the substrate SUB may be removed during the manufacturing process, and thus the substrate SUB is illustrated by a dotted line in FIG. 4.

The substrate SUB may include a first region and a second region. The first region may be a region in which the memory cells are formed, and the second region may be a region in which contacts (or contact plugs) for transmitting electrical signals to the memory cells are formed. The first region and the second region may be referred to as a cell region and an extension region, respectively. For convenience, only the first region is illustrated in FIG. 4.

The substrate SUB may further include a third region in which peripheral circuit patterns including sense amplifiers, etc. are formed. The third region may be referred to as a peripheral circuit region. In some example embodiments, the third region may at least partially surround the first and second regions, or may be disposed under or over the substrate SUB, so that the semiconductor memory device may have a cell over periphery (COP) structure or a periphery over cell (POC) structure. As used herein, the phrase “at least partially surround” is understood to mean that the surrounding element contacts the surrounded element on at least one side or portion thereof, may contact the surrounded element on two sides, whether those sides are opposite sides or proximate sides, may contact the surrounded element on more than two sides, and may even completely surround the surrounded element.

Each of the local bitlines LBL may extend in the first direction D1 on the first region of the substrate SUB, and a plurality of local bitlines LBL may be spaced apart from each other in the second and third directions D2 and D3. The memory cells and transistors included in the local bitline multiplexers may be formed between two adjacent local bitlines LBL.

Each of the global bitlines GBL may extend in the second direction D2 on the first region of the substrate SUB and on and under the local bitlines LBL, and a plurality of global bitlines GBL may be spaced apart from each other in the third direction D3.

Each of the wordlines WL and each of the control lines CL may extend in the third direction D3 on the first and second regions of the substrate SUB, a plurality of wordlines WL and a plurality of control lines CL may be spaced apart from each other in the second direction D2, and one control line CL, some wordlines WL and another control line CL may be stacked in the first direction D1.

Although not illustrated in detail, the semiconductor memory device may further include wordline contacts and control contacts. For example, each of the wordline contacts and each of the control contacts may extend in the first direction D1 on the second region of the substrate SUB, and may be electrically connected to one of the wordlines WL and one of the control lines CL, respectively. For example, the wordlines WL and the control lines CL may be disposed scalariformly, that is, in a step shape (e.g., in the third direction D3 in a stepwise manner) on the second region of the substrate SUB, and the wordline contacts and the control contacts be formed and/or disposed on the step shape.

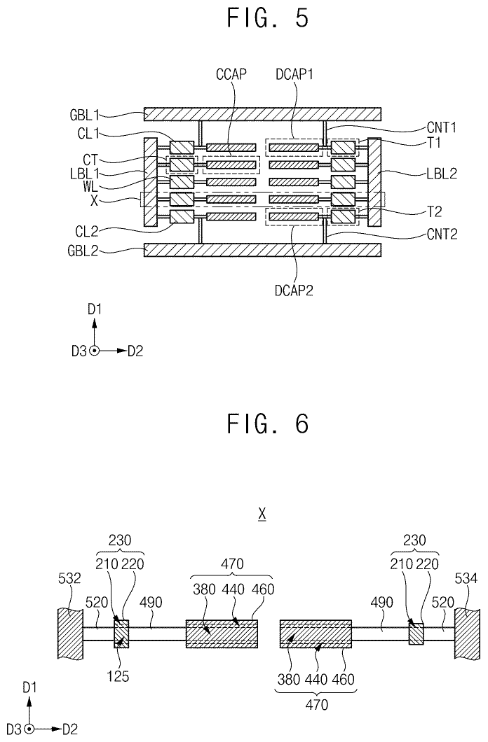

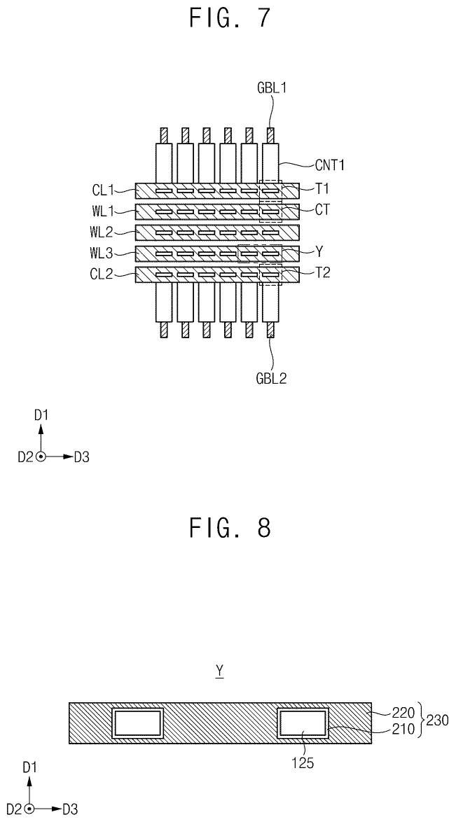

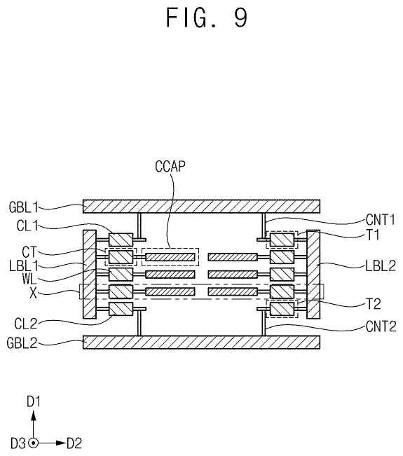

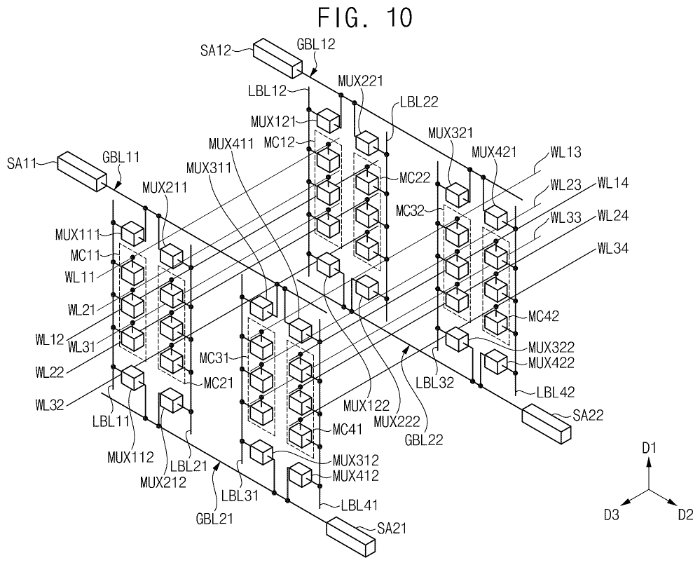

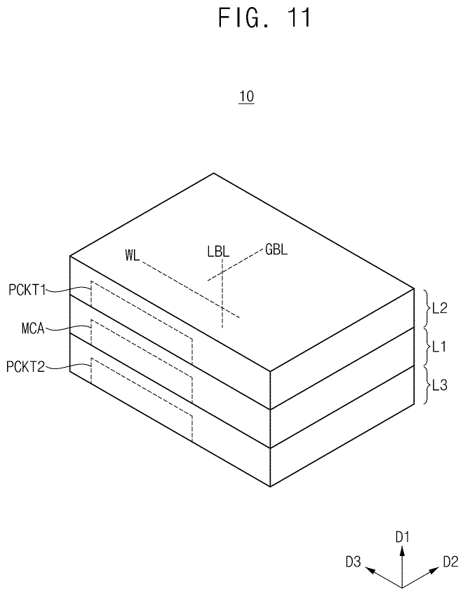

FIGS. 5, 6, 7, 8 and 9 are cross-sectional views for describing a semiconductor memory device of FIG. 4. For example, FIGS. 5 and 9 are cross-sectional views taken along a line I-I′ in FIG. 4, FIG. 6 is a detailed cross-sectional view of a region X in FIG. 5, FIG. 7 is a cross-sectional view taken along a line II-II′ in FIG. 4, and FIG. 8 is a detailed cross-sectional view of a region Y in FIG. 7.

Referring to FIGS. 5, 6, 7 and 8, the memory cells formed between local bitlines LBL1 and LBL2 may include cell transistors CT and cell capacitors CCAP. First control lines CL1 may be formed on wordlines WL, WL1, WL2 and WL3, and second control lines CL2 may be formed under the wordlines WL, WL1, WL2 and WL3. Among the local bitline multiplexers, first local bitline multiplexers that are adjacent to first global bitline GBL1 on the upper side may include first selection transistors T1, and may further include first dummy capacitors DCAP1. Among the local bitline multiplexers, second local bitline multiplexers that are adjacent to second global bitline GBL2 on the lower side may include second selection transistors T2, and may further include second dummy capacitors DCAP2.

For example, the local bitlines LBL1 and LBL2 may correspond to the local bitlines LBL11 and LBL21 in FIGS. 1 and 2, the first and second global bitlines GBL1 and GBL2 may correspond to the first and second global bitlines GBL11 and GBL21 in FIGS. 1 and 2, and the wordlines WL, WL1, WL2 and WL3 may correspond to the wordlines WL11, WL21, WL31, WL12, WL22 and WL32 in FIGS. 1 and 2. For example, the first selection transistors T1 may correspond to the first selection transistors T111 and T211 in FIG. 2, the second selection transistors T2 may correspond to the second selection transistors T112 and T212 in FIG. 2, the first control lines CL1 may correspond to the first control lines CL11 and CL12 in FIG. 2, and the second control lines CL2 may correspond to the second control lines CL21 and CL22 in FIG. 2.

For example, structures 532 and 534 in FIG. 6 may represent or correspond to two local bitlines LBL1 and LBL2 that extend in the first direction D1 and are spaced apart in the second direction D2. For example, an upper surface of each of the local bitlines 532 and 534 may have a shape of, e.g., a polygon, a polygon with rounded corners, a circle, an ellipse, etc.

Between two adjacent local bitlines 532 and 534, two memory cells may be formed at the remaining levels other than the uppermost and lowermost levels. For example, each memory cell may include the cell capacitor CCAP and the cell transistor CT. For example, in FIG. 6, one cell transistor may be formed between a cell capacitor 470 on the left side and the local bitline 532, and another cell transistor may be formed between a cell capacitor 470 on the right side and the local bitline 534. For example, each cell transistor may include a second source/drain layer 490, a channel 125 and a first source/drain layer 520 that are sequentially disposed between the capacitor 470 and each of the local bitlines 532 and 534, and a gate structure 230 surrounding the channel 125.

In some example embodiments, the cell capacitor 470 may include a first capacitor electrode 380 having a pillar shape extending in the second direction D2, a dielectric pattern 440 having a shape of a hollow cylinder that may surround a surface, for example, lower and upper surfaces and opposite sidewalls in the third direction D3 of the first capacitor electrode 380, and a second capacitor electrode 460 having a hollow cylinder that may surround a surface, for example, lower and upper surfaces and opposite outer sidewalls in the third direction D3 of the dielectric pattern 440. However, example embodiments are not necessarily limited thereto, and for example, the first capacitor electrode 380 may have a shape of a hollow cylinder instead of the pillar shape, and the second capacitor electrode 460 may have a shape of a hollow cylinder instead of the pillar shape.

In some example embodiments, a cross-section in the third direction D3 of the first capacitor electrode 380 may have a shape of a rectangle. However, example embodiments are not necessarily limited thereto, and the cross-section in the third direction D3 of the first capacitor electrode 380 may have a shape of, e.g., a polygon, a polygon with rounded corners, a circle, an ellipse, etc.

Each of the first and second capacitor electrodes 380 and 460 may include an electrically conductive material, e.g., a metal, a metal nitride, a metal silicide, doped silicon-germanium, etc. The dielectric pattern 440 may include a metal oxide having a high dielectric constant, e.g., hafnium oxide, zirconium oxide, etc., or a ferroelectric material. As used herein, the phrase, “high dielectric constant” may be understood to be a dielectric constant greater than that of silicon oxide.

The channel 125 may include a semiconductor material, e.g., silicon, germanium, silicon-germanium, etc. Alternatively, the channel 125 may include an oxide semiconductor material such as zinc tin oxide (ZTO), indium zinc oxide (IZO), zinc oxide (ZnOₓ), indium gallium zinc oxide (IGZO), indium gallium silicon oxide (IGSO), Indium oxide (InOₓ, In₂O₃), tin oxide (SnO₂), titanium oxide (TiOₓ), zinc oxide nitride (ZnₓO_{y}N_{z}), magnesium zinc oxide (MgₓZn_{y}O_{z}), indium zinc oxide (InₓZn_{y}Oₐ), indium gallium zinc oxide (InₓGa_{y}Zn_{z}Oₐ), zirconium indium zinc oxide (ZrₓIn_{y}Zn_{z}Oₐ), hafnium indium zinc oxide (HfₓIn_{y}Zn_{z}Oₐ), tin indium zinc oxide (SnₓIn_{y}Zn₂Oₐ), aluminum tin indium zinc oxide (AlₓSn_{y}In_{z}ZnₐO_{d}), silicon indium zinc oxide (SiₓIn_{y}Zn₂Oₐ), zinc tin oxide (ZnₓSn_{y}O_{z}), aluminum zinc tin oxide (AlₓZn_{y}Sn_{z}Oₐ), gallium zinc tin oxide (GaₓZn_{y}Sn_{z}Oₐ), zirconium zinc tin oxide (ZrₓZn_{y}Sn_{z}Oₐ), and/or indium gallium silicon oxide (InGaSiO).

Each of the first and second source/drain layers 520 and 490 may include substantially the same material as the channel 125, however, n-type or p-type impurities may be doped thereinto. The first and second source/drain layers 520 and 490 may include the same conductivity type of impurities.

In some example embodiments, the gate structure 230 may include a gate insulation pattern 210 covering a surface, for example, lower and upper surfaces and opposite sidewalls in the third direction D3 of the channel 125, and a gate electrode 220 covering a surface, for example, lower and upper surfaces and opposite outer sidewalls in the third direction D3 of the gate insulation pattern 210. Thus, the channel 125 may extend through the gate structure 230 in the second direction D2, and the gate structure 230 may have a gate all around (GAA) structure surrounding the channel 125.

Alternatively, the gate structure 230 may have a single gate structure or a double gate structure instead of the GAA structure. For example, the gate structure 230 may be disposed on or beneath the channel 125, or two gate structures 230 may be disposed on and beneath, respectively, the channel 125, instead of surrounding the channel 125.

As a result, if only the gate structure 230 is electrically connected to the channel 125, the gate structure 230 may have various other types of structures.

In addition, between two adjacent local bitlines 532 and 534, two first selection transistors T1 and two first dummy capacitors DCAP1 may be formed at the uppermost level, and two second selection transistors T2 and two second dummy capacitors DCAP2 may be formed at the lowermost level. For example, each of the selection transistors T1 and T2 may have a structure substantially the same as that of the cell transistor CT included in each memory cell, and each of the dummy capacitors DCAP1 and DCAP2 may have a structure substantially the same as that of the cell capacitor CCAP included in each memory cell.

In some example embodiments, the semiconductor memory device may further include first contacts CNT1 and second contacts CNT2. For example, the first contacts CNT1 may be disposed between the first global bitline GBL1 and the first local bitline multiplexers (e.g., between the first global bitline GBL1 and the first selection transistors T1), and the first selection transistors T1 may be connected to the first global bitline GBL1 through the first contacts CNT1. For example, the second contacts CNT2 may be disposed between the second global bitline GBL2 and the second local bitline multiplexers (e.g., between the second global bitline GBL2 and the second selection transistors T2), and the second selection transistors T2 may be connected to the second global bitline GBL2 through the second contacts CNT2. For example, each of the first contacts CNT1 may be connected to a junction between each of the first selection transistors T1 and each of the first dummy capacitors DCAP1, and each of the second contacts CNT2 may be connected to a junction between each of the second selection transistors T2 and each of the second dummy capacitors DCAP2.

In some example embodiments, the gate electrodes 220, which surround the channels 125 arranged along the third direction D3 at the same level and the gate insulation patterns 210 covering the channels 125 and are disposed adjacent to each other in the third direction D3, may be connected to each other, and thus may form one of the wordlines WL, WL1, WL2 and WL3 and/or one of the control lines CL1 an CL2 extending in the third direction D3 on the first and second regions of the substrate SUB. For example, the gate electrode 220 at the uppermost level may form the first control line CL1, the gate electrode 220 at the lowermost level may form the second control line CL2, and the gate electrodes 220 at the remaining levels other than the uppermost and lowermost levels may form the wordlines WL, WL1, WL2 and WL3.

The gate electrode 220 may include an electrically conductive material, e.g., a metal, a metal nitride, a metal silicide, etc., and the gate insulation pattern 210 may include an oxide, e.g., silicon oxide, a metal oxide, etc.

Referring to FIG. 9, an example of FIG. 9 may be substantially the same as the example of FIG. 5, except that the first and second dummy capacitors DCAP1 and DCAP2 are omitted in the example of FIG. 9. The descriptions repeated with or overlapping with descriptions of FIGS. 5, 6, 7 and 8 will be omitted in the interest of brevity.

Between two adjacent local bitlines 532 and 534, the structures corresponding to the capacitor 470 may not be formed and may be omitted at the uppermost and lowermost levels. Therefore, only two first selection transistors T1 may be formed at the uppermost level, and the first dummy capacitors DCAP1 may be omitted. Similarly, only two second selection transistors T2 may be formed at the lowermost level, and the second dummy capacitors DCAP2 may be omitted.

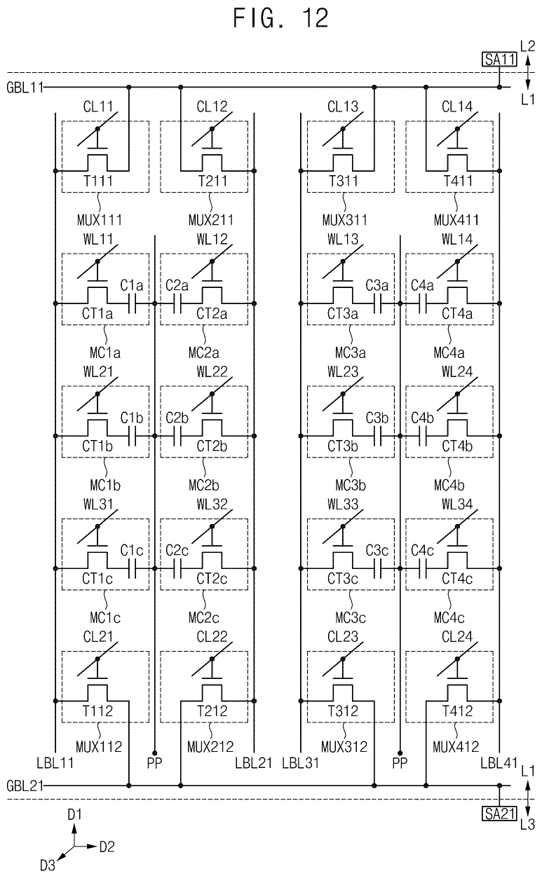

FIG. 10 is a perspective view of a semiconductor memory device according to example embodiments. The descriptions repeated with or overlapping with descriptions of FIG. 1 will be omitted in the interest of brevity.

Referring to FIG. 10, a portion of a memory cell array of a semiconductor memory device is illustrated, and a portion of a peripheral circuit connected to the portion of the memory cell array is illustrated. As compared with the semiconductor memory device of FIG. 1, the semiconductor memory device of FIG. 10 may further include a plurality of first sense amplifiers SA11 and SA12 and a plurality of second sense amplifiers SA21 and SA22.

For example, the plurality of memory cells MC11, MC21, MC31, MC41, MC12, MC22, MC32 and MC42, the plurality of local bitlines LBL11, LBL21, LBL31, LBL41, LBL12, LBL22, LBL32 and LBL42, the plurality of wordlines WL11, WL21, WL31, WL12, WL22, WL32, WL13, WL23, WL33, WL14, WL24 and WL34, the plurality of first global bitlines GBL11 and GBL12, the plurality of second global bitlines GBL21 and GBL22, the plurality of first local bitline multiplexers MUX111, MUX211, MUX311, MUX411, MUX121, MUX221, MUX321 and MUX421, and the plurality of second local bitline multiplexers MUX112, MUX212, MUX312, MUX412, MUX122, MUX222, MUX322 and MUX422 may be included in the memory cell array (or the portion thereof). For example, the plurality of first sense amplifiers SA11 and SA12 and the plurality of second sense amplifiers SA21 and SA22 may be included in the peripheral circuit (or the part thereof).

The plurality of first sense amplifiers SA11 and SA12 may be electrically connected to the plurality of first global bitlines GBL11 and GBL12, and may drive the plurality of first global bitlines GBL11 and GBL12 and the plurality of local bitlines LBL11, LBL21, LBL31, LBL41, LBL12, LBL22, LBL32 and LBL42. The plurality of second sense amplifiers SA21 and SA22 may be electrically connected to the plurality of second global bitlines GBL21 and GBL22, and may drive the plurality of second global bitlines GBL21 and GBL22 and the plurality of local bitlines LBL11, LBL21, LBL31, LBL41, LBL12, LBL22, LBL32 and LBL42.

For example, the first sense amplifier SA11 may be electrically connected to the first global bitline GBL11, and may drive the first global bitline GBL11 and one of the local bitlines LBL11, LBL21, LBL31 and LBL41 when the first global bitline GBL11 is electrically connected to one of the local bitlines LBL11, LBL21, LBL31 and LBL41 through one of the first local bitline multiplexers MUX111, MUX211, MUX311 and MUX411. For example, the first sense amplifier SA12 may be electrically connected to the first global bitline GBL12, and may drive the first global bitline GBL12 and one of the local bitlines LBL12, LBL22, LBL32 and LBL42 when the first global bitline GBL12 is electrically connected to one of the local bitlines LBL12, LBL22, LBL32 and LBL42 through one of the first local bitline multiplexers MUX121, MUX221, MUX321 and MUX421.

Similarly, the second sense amplifier SA21 may be electrically connected to the second global bitline GBL21, and may drive the second global bitline GBL21 and one of the local bitlines LBL11, LBL21, LBL31 and LBL41 when the second global bitline GBL21 is electrically connected to one of the local bitlines LBL11, LBL21, LBL31 and LBL41. The second sense amplifier SA22 may be electrically connected to the second global bitline GBL22, and may drive the second global bitline GBL22 and one of the local bitlines LBL12, LBL22, LBL32 and LBL42 when the second global bitline GBL22 is electrically connected to one of the local bitlines LBL12, LBL22, LBL32 and LBL42.

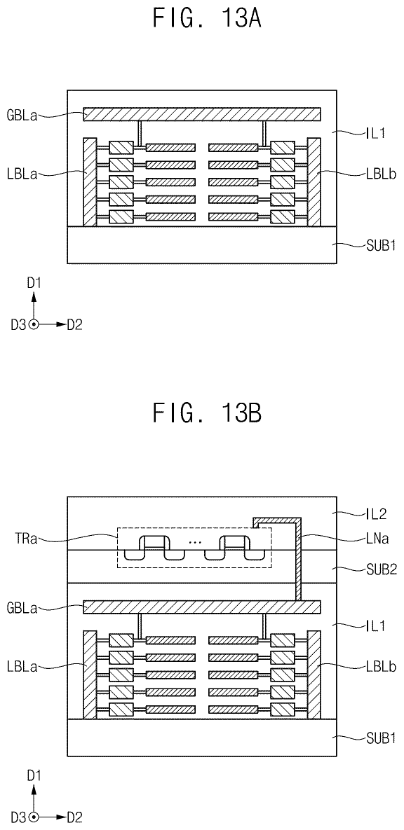

FIG. 11 is a perspective view of a semiconductor memory device according to example embodiments.

Referring to FIG. 11, a semiconductor memory device 10 includes a first semiconductor layer L1, a second semiconductor layer L2 and a third semiconductor layer L3.

The first semiconductor layer L1, the second semiconductor layer L2 and the third semiconductor layer L3 are disposed or stacked in the first direction D1. For example, the second semiconductor layer L2 may be stacked on the first semiconductor layer L1 in the first direction D1, and the first semiconductor layer L1 may be disposed under (e.g., directly beneath or indirectly beneath) the second semiconductor layer L2 in the first direction D1. For example, the third semiconductor layer L3 may be disposed the first semiconductor layer L1 in the first direction D1, and the first semiconductor layer L1 may be stacked on the third semiconductor layer L3 in the first direction D1. However, example embodiments are not limited thereto. For example, the semiconductor memory device 10 may be turned over during the manufacturing process, and thus the arrangement of the first, second and third semiconductor layers L1, L2 and L3 may be changed.

The first semiconductor layer L1 includes a plurality of wordlines WL, a plurality of local bitlines LBL, a plurality of global bitlines GBL and a memory cell array MCA. Thus, the first semiconductor layer L1 may be referred to as a memory cell region (MCR) and/or a cell wafer.

For example, as will be described with reference to FIGS. 13A, 13B, 13C and 13D, the first semiconductor layer L1 may include a first substrate, and the plurality of wordlines WL, the plurality of local bitlines LBL, the plurality of global bitlines GBL and the memory cell array MCA may be formed and/or disposed on the first substrate.

The second semiconductor layer L2 and the third semiconductor layer L3 include a first peripheral circuit PCKT1 and a second peripheral circuit PCKT2 that control the memory cell array MCA, respectively. Thus, each of the second and third semiconductor layers L2 and L3 may be referred to as a peripheral circuit region (PCR) and/or a peripheral wafer (or a core wafer).

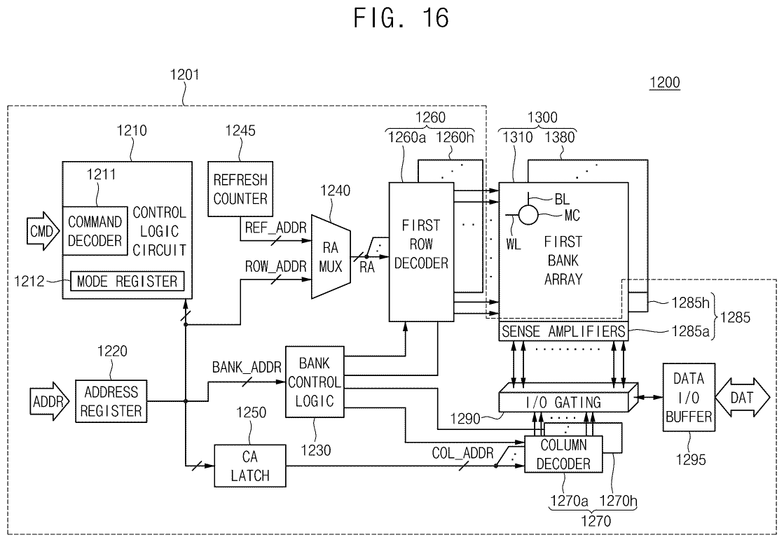

For example, as will be described with reference to FIGS. 13A, 13B, 13C and 13D, the second semiconductor layer L2 and the third semiconductor layer L3 may include a second substrate and a third substrate, respectively, and the first peripheral circuit PCKT1 and the second peripheral circuit PCKT2 may be formed and/or disposed on the second substrate and the third substrate, respectively. For example, as will be described with reference to FIG. 16, the first and second peripheral circuits PCKT1 and PCKT2 may include a control logic circuit, a sense amplifier unit, etc.

In some example embodiments, the semiconductor layers L1, L2 and L3 may be manufactured separately, and then the semiconductor layers L1, L2 and L3 may be connected to each other by a bonding scheme (or method). For example, the bonding scheme may represent a method of electrically or physically connecting a bonding pad (or bonding metal pattern) formed in the first semiconductor layer L1 with a bonding pad formed in the second semiconductor layer L2, and a method of electrically or physically connecting a bonding pad formed in the first semiconductor layer L1 with a bonding pad formed in the third semiconductor layer L3.

In some example embodiments, the bonding pads may be formed of copper (Cu), and the bonding scheme may be a Cu—Cu bonding scheme. Alternatively, the bonding pads may be formed of aluminum (Al) or tungsten (W).

However, example embodiments are not limited thereto, and various bonding schemes, such as a hybrid bonding scheme and a dielectric bonding scheme, may be used to electrically or physically connect the semiconductor layers L1, L2 and L3 with each other.

The semiconductor memory device 10 according to example embodiments may have or adopt a structure in which the peripheral circuits PCKT1 and PCKT2 and the memory cell array MCA are stacked, e.g., a periphery over cell (POC) structure or a cell over periphery (COP) structure in which the peripheral circuits PCKT1 and PCKT2 are stacked on and/or under the memory cell array MCA. Accordingly, the semiconductor memory device 10 may have a relatively small size.

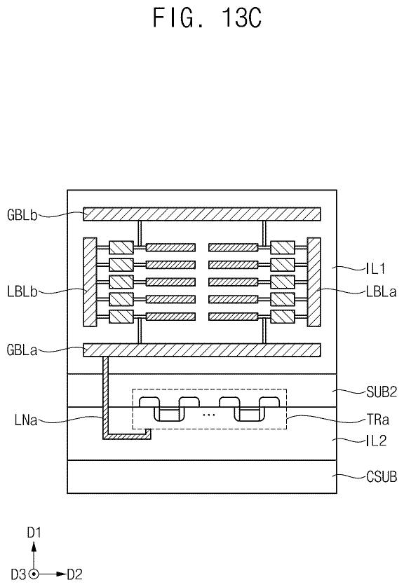

FIG. 12 is a circuit diagram illustrating an example of a semiconductor memory device of FIGS. 10 and 11.

Referring to FIG. 12, an example of components that are connected to the local bitlines LBL11, LBL21, LBL31 and LBL41, the first global bitline GBL11 and the second global bitline GBL21 in the semiconductor memory device of FIGS. 10 and 11 is illustrated. The descriptions repeated with or overlapping with descriptions of FIGS. 2, 10 and 11 will be omitted in the interest of brevity.

The local bitlines LBL11, LBL21, LBL31 and LBL41, the wordlines WL11, WL21, WL31, WL12, WL22, WL32, WL13, WL23, WL33, WL14, WL24 and WL34, the control lines CL11, CL12, CL13, CL14, CL21, CL22, CL23 and CL24, the memory cells MC1a, MC1b, MC1c, MC2a, MC2b, MC2c, MC3a, MC3b, MC3c, MC4a, MC4b and MC4c, the local bitline multiplexers MUX111, MUX211, MUX311, MUX411, MUX112, MUX212, MUX312 and MUX412, and the global bitlines GBL11 and GBL21 may be disposed in the first semiconductor layer L1 (e.g., in the cell wafer), and may be disposed on the first substrate.

The first sense amplifier SA11 may be disposed in the second semiconductor layer L2 (e.g., in the peripheral wafer) on the first semiconductor layer L1, and may be disposed on the second substrate. The second sense amplifier SA21 may be disposed in the third semiconductor layer L3 (e.g., in the peripheral wafer) under the first semiconductor layer L1, and may be disposed on the third substrate. In some example embodiments, when the second semiconductor layer L2 and/or the third semiconductor layer L3 are turned over, the first sense amplifier SA11 may be disposed under the second substrate, and/or the second sense amplifier SA21 may be disposed under the third substrate.

However, example embodiments are not limited thereto, and at least one component may be additionally disposed in the semiconductor layers L1, L2 and L3.

Although example embodiments are described based on that the first sense amplifier SA11 connected to the upper global bitline GBL11 is disposed in the upper semiconductor layer L2 and the second sense amplifier SA21 connected to the lower global bitline GBL21 is disposed in the lower semiconductor layer L3, example embodiments are not limited thereto. For example, both the first and second sense amplifiers SA11 and SA21 may be disposed in the second semiconductor layer L2 or in the third semiconductor layer L3, and the arrangement of the first and second sense amplifiers SA11 and SA21 may be implemented in various other manners.

Although example embodiments are described based on that the first semiconductor layer L1 including the memory cell array MCA is disposed in the middle and the second and third semiconductor layers L2 and L3 including the peripheral circuits PCKT1 and PCKT2 are disposed on and under the first semiconductor layer L1, example embodiments are not limited thereto. For example, both the second and third semiconductor layers L2 and L3 may be disposed on or under the first semiconductor layer L1.

Although example embodiments are described based on that the semiconductor memory device includes one semiconductor layer L1 including the memory cell array MCA and two semiconductor layers L2 and L3 including the peripheral circuits PCKT1 and PCKT2, example embodiments are not limited thereto. For example, the semiconductor memory device may include one cell wafer and one peripheral wafer, or the semiconductor memory device may include two or more cell wafers and/or three or more peripheral wafers, and the sense amplifiers may be disposed in the peripheral wafers in various manners.

FIGS. 13A, 13B, 13C and 13D are cross-sectional views for describing a method of manufacturing a semiconductor memory device according to example embodiments.

Referring to 13A, 13B, 13C and 13D, an example of manufacturing the semiconductor memory device described with reference to FIGS. 11 and 12 is illustrated. The descriptions repeated with or overlapping with descriptions of FIGS. 4 through 12 will be omitted in the interest of brevity.

As illustrated in FIG. 13A, a portion of the first semiconductor layer L1 may be formed by forming structures for the memory cell array MCA.

For example, structures associated with (or related to) the wordlines WL, the control lines CL, the cell transistors CT and the selection transistors T1 and T2 may be formed on the first substrate SUB1. Thereafter, structures associated with local bitlines LBLa and LBLb corresponding to the local bit lines LBL1 and LBL2 may be formed, and then structures associated with the cell capacitors CCAP and the dummy capacitors DCAP1 and DCAP2 may be formed. Thereafter, one of the contacts CNT1 and CNT2 may be formed, and then a global bitline GBLa corresponding to one of the global bitlines GBL1 and GBL2 may be formed, and then a first insulating layer IL1 may be formed.

The first substrate SUB1 may be a supporting layer that supports components of the first semiconductor layer L1. For example, the first substrate SUB1 may be a silicon substrate, and may be referred to as a base substrate. The first insulating layer IL1 may cover the components of the first semiconductor layer L1. For example, the first insulating layer IL1 may include a plurality of insulating layers. Although not illustrated in FIG. 13A, various conductive lines and contacts may be further formed in the first semiconductor layer L1.

As illustrated in FIG. 13B, the second semiconductor layer L2 may be formed, and the structure of FIG. 13A and the second semiconductor layer L2 may be bonded with each other.

For example, first transistors Tra for the first peripheral circuit PCKT1 may be formed on the second substrate SUB2, and then first connection lines Lna for electrical connections between components may be formed, and then a second insulating layer IL2 may be formed. As such, the forming of the second semiconductor layer L2 may be completed.

Similar to the first substrate SUB1 and the first insulating layer IL1, the second substrate SUB2 may be a supporting layer that supports components of the second semiconductor layer L2, and the second insulating layer IL2 may cover the components of the second semiconductor layer L2. For example, the first connecting lines Lna may include at least one conductive line, at least one contact and/or at least one via. Although not illustrated in FIG. 13B, various conductive lines and contacts may be further formed in the second semiconductor layer L2.

Thereafter, the second semiconductor layer L2 may be bonded with the structure of FIG. 13A. Although not illustrated in FIG. 13B, bonding pads of the first semiconductor layer L1 and bonding pads of the second semiconductor layer L2 may be electrically and/or physically connected to each other.

As illustrated in FIG. 13C, the structure of FIG. 13B may be turned over, and the entire of the first semiconductor layer L1 may be formed by forming additional structures for the memory cell array MCA.

For example, the structure of FIG. 13B, in which the portion of the first semiconductor layer L1 of FIG. 13A and the second semiconductor layer L2 are bonded, may be turned over. Thereafter, a carrier substrate CSUB may be disposed under the structure of FIG. 13B that has been turned over, and then the first substrate SUB1 may be removed by a process such as grinding. Thereafter, another one of the contacts CNT1 and CNT2 may be formed, and then a global bitline GBLb corresponding to another one of the global bitlines GBL1 and GBL2 may be formed, and then the first insulating layer IL1 may be further formed. As such, the forming of the first semiconductor layer L1 may be completed.

As illustrated in FIG. 13D, the third semiconductor layer L3 may be formed, and the structure of FIG. 13C and the third semiconductor layer L3 may be bonded with each other.

For example, second transistors TRb for the second peripheral circuit PCKT2 may be formed on the third substrate SUB3, and then second connection lines LNb for electrical connections between components may be formed, and then a third insulating layer IL3 may be formed. As such, the forming of the third semiconductor layer L3 may be completed.

Similar to the second substrate SUB2 and the second insulating layer IL2, the third substrate SUB3 may be a supporting layer that supports components of the third semiconductor layer L3, and the third insulating layer IL3 may cover the components of the third semiconductor layer L3. For example, the second connection lines LNb may include at least one conductive line, at least one contact and/or at least one via. Although not illustrated in FIG. 13D, various conductive lines and contacts may be further formed in the third semiconductor layer L3.

Thereafter, the third semiconductor layer L3 may be bonded with the structure of FIG. 13C. Although not illustrated in FIG. 13D, bonding pads of the first semiconductor layer L1 and bonding pads of the third semiconductor layer L3 may be electrically and/or physically connected to each other.

Thereafter, input/output pads PD for connections with an external device may be formed. Although not illustrated in FIG. 13D, the carrier substrate CSUB may be removed. As such, the forming of the semiconductor memory device may be completed.

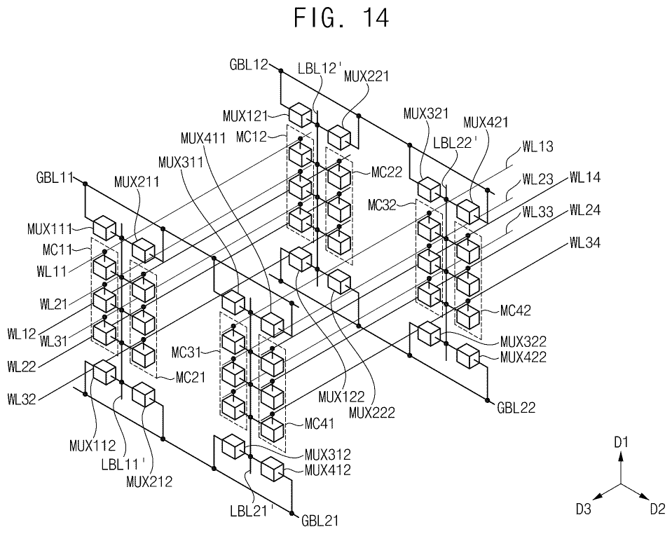

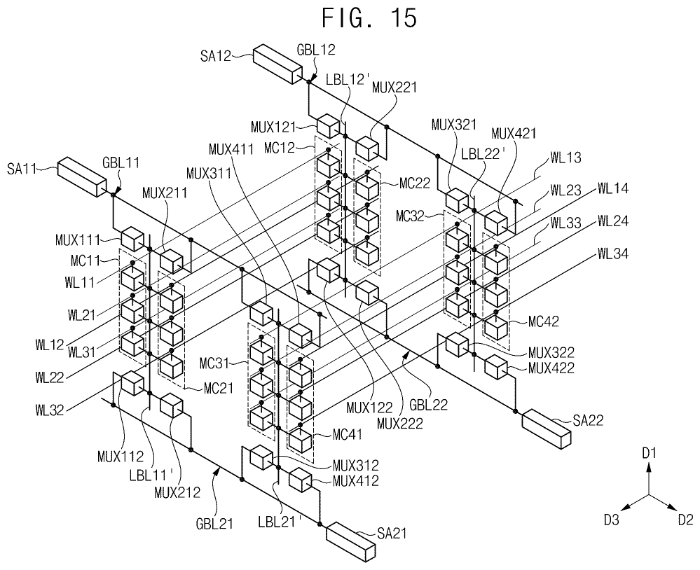

FIGS. 14 and 15 are perspective views of a semiconductor memory device according to example embodiments. The descriptions repeated with or overlapping with descriptions of FIGS. 1 and 10 will be omitted in the interest of brevity.

Referring to FIG. 14, a portion of a memory cell array of a semiconductor memory device is illustrated. As compared with the semiconductor memory device of FIG. 1, the semiconductor memory device of FIG. 14 may be implemented such that some memory cells additionally share one local bitline.

In some example embodiments, some memory cells that are arranged adjacently along the second direction D2 may be electrically connected to the same local bitline. For example, two cell strings, which are arranged adjacent to a first side and a second side of one local bitline and along the second direction D2, and memory cells included therein may be electrically connected to the one local bitline and may share the one local bitline.

For example, the memory cells MC11 and MC21 may be adjacent to each other in the second direction D2, and may share the local bitline LBL11′. For example, the memory cells MC11 may be adjacent to a first side (e.g., the left side) of the local bitline LBL11′, the memory cells MC21 may be adjacent to a second side (e.g., the right side) of the local bitline LBL11′, and the memory cells MC11 and MC21 may be commonly connected to the same local bitline (e.g., the local bitline LBL11′).

For example, the memory cells MC31 and MC41 may be adjacent to each other in the second direction D2, and may share the local bitline LBL21′. For example, the memory cells MC31 may be adjacent to a first side (e.g., the left side) of the local bitline LBL21′, the memory cells MC41 may be adjacent to a second side (e.g., the right side) of the local bitline LBL21′, and the memory cells MC31 and MC41 may be commonly connected to the same local bitline (e.g., the local bitline LBL21′).

Similarly, the memory cells MC12 and the memory cells MC22 may be adjacent to a first side and a second side of the local bitline LBL12′, respectively, may be electrically connected to the local bitline LBL12′, and may share the local bitline LBL12′. The memory cells MC32 and the memory cells MC42 may be adjacent to a first side and a second side of the local bitline LBL22′, respectively, may be electrically connected to the local bitline LBL22′, and may share the local bitline LBL22′.

In some example embodiments, two cell strings, two first local bitline multiplexers and two second local bitline multiplexers may be connected to one local bitline.

As described above, one local bitline may be shared by adjacent memory cells, and thus the semiconductor memory device may have the increased degree of integration and improved characteristic.

Referring to FIG. 15, a portion of a memory cell array of a semiconductor memory device is illustrated, and a portion of a peripheral circuit connected to the portion of the memory cell array is illustrated. As compared with the semiconductor memory device of FIG. 10, the semiconductor memory device of FIG. 15 may be implemented such that some memory cells additionally share one local bitline. The connections between the local bitlines LBL11′, LBL21′, LBL12′ and LBL22′ and the memory cells MC11, MC21, MC31, MC41, MC12, MC22, MC32 and MC42 may be substantially the same as those described with reference to FIG. 14.

In some example embodiments, although not illustrated in detail, the semiconductor memory device may be implemented with a wordline merging structure in which wordlines (e.g., the wordlines WL12 and WL13) connected to memory cells (e.g., the memory cells MC21 and MC31), which are disposed at the same level, are adjacent to each other in the second direction D2 and do not share a local bitlines, are merged into one wordline.

In some example embodiments, the semiconductor memory device according to example embodiments may be implemented by combining two or more of the examples described with reference to FIGS. 1 through 15.

FIG. 16 is a block diagram illustrating a semiconductor memory device according to example embodiments.

Referring to FIG. 16, a semiconductor memory device 1200 may include a peripheral circuit 1201 and a memory cell array 1300. The peripheral circuit 1201 may include a control logic circuit 1210, an address register 1220, a bank control logic circuit 1230, a row address multiplexer 1240, a refresh counter 1245, a column address latch 1250, a row decoder 1260, a column decoder 1270, a sense amplifier unit 1285, an input/output (I/O) gating circuit 1290 and a data I/O buffer 1295. For example, the semiconductor memory device 1200 may be one of various volatile memory devices such as a dynamic random access memory (DRAM) device.

The memory cell array 1300 may include first to eighth bank arrays 1310 to 1380 (e.g., first to eighth bank arrays 1310, 1320, 1330, 1340, 1350, 1360, 1370 and 1380). The row decoder 1260 may include first to eighth bank row decoders 1260a to 1260h connected respectively to the first to eighth bank arrays 1310 to 1380. The column decoder 1270 may include first to eighth bank column decoders 1270a to 1270h connected respectively to the first to eighth bank arrays 1310 to 1380. The sense amplifier unit 1285 may include first to eighth bank sense amplifiers 1285a to 1285h connected respectively to the first to eighth bank arrays 1310 to 1380.

The first to eighth bank arrays 1310 to 1380, the first to eighth bank row decoders 1260a to 1260h, the first to eighth bank column decoders 1270a to 1270h, and the first to eighth bank sense amplifiers 1285a to 1285h may form first to eighth banks. Each of the first to eighth bank arrays 1310 to 1380 may include a plurality of wordlines WL, a plurality of bitlines BL, and a plurality of memory cells MC that are at intersections of the wordlines WL and the bitlines BL. For example, each of the plurality of bitlines BL may include the local bitline LBL and the global bitline GBL that are selectively connected by the local bitline multiplexer.

Although FIG. 16 illustrates the semiconductor memory device 1200 including eight banks (and eight bank arrays, eight row decoders, and so on), the semiconductor memory device 1200 may include any number of banks; for example, one, two, four, eight, sixteen, or thirty two banks, or any number therebetween one and thirty two.

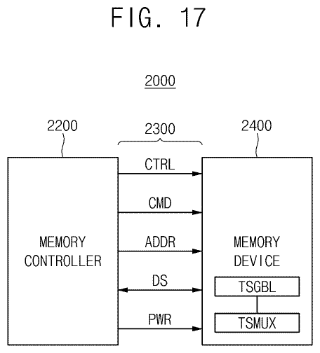

The address register 1220 may receive the address ADDR including a bank address BANK_ADDR, a row address ROW_ADDR, and a column address COL_ADDR from a memory controller (e.g., a memory controller 2200 in FIG. 17). The address register 1220 may provide the received bank address BANK_ADDR to the bank control logic circuit 1230, may provide the received row address ROW_ADDR to the row address multiplexer 1240, and may provide the received column address COL_ADDR to the column address latch 1250.

The bank control logic circuit 1230 may generate bank control signals in response to the bank address BANK_ADDR. One of the first to eighth bank row decoders 1260a to 1260h corresponding to the bank address BANK_ADDR may be activated in response to the bank control signals, and one of the first to eighth bank column decoders 1270a to 1270h corresponding to the bank address BANK_ADDR may be activated in response to the bank control signals.

The row address multiplexer 1240 may receive the row address ROW_ADDR from the address register 1220, and may receive a refresh row address REF_ADDR from the refresh counter 1245. The row address multiplexer 1240 may selectively output the row address ROW_ADDR or the refresh row address REF_ADDR as a row address RA. The row address RA that is output from the row address multiplexer 1240 may be applied to the first to eighth bank row decoders 1260a to 1260h.

The activated one of the first to eighth bank row decoders 1260a to 1260h may decode the row address RA that is output from the row address multiplexer 1240, and may activate in the corresponding bank array a wordline WL corresponding to the row address RA. For example, the activated bank row decoder may generate a wordline driving voltage, and may apply the wordline driving voltage to the wordline WL corresponding to the row address RA.

The column address latch 1250 may receive the column address COL_ADDR from the address register 1220, and may temporarily store the received column address COL_ADDR. In some example embodiments, in a burst mode, the column address latch 1250 may generate column addresses that increment from the received column address COL_ADDR. The column address latch 1250 may apply the temporarily stored or generated column address to the first to eighth bank column decoders 1270a to 1270h.

The activated one of the first to eighth bank column decoders 1270a to 1270h may decode the column address COL_ADDR that is output from the column address latch 1250, and may control the I/O gating circuit 1290 to output data corresponding to the column address COL_ADDR.

The I/O gating circuit 1290 may include circuitry configured to gate input/output data. The I/O gating circuit 1290 may further include read data latches configured to store data that is output from the first to eighth bank arrays 1310 to 1380, and may also include write control devices for writing data to the first to eighth bank arrays 1310 to 1380.

Data DAT read from one of the first to eighth bank arrays 1310 to 1380 may be sensed by a sense amplifier connected to the one bank array from which the data DAT is to be read, and may be stored in the read data latches. The data DAT stored in the read data latches may be provided to the memory controller via the data I/O buffer 1295. Data DAT to be written in one of the first to eighth bank arrays 1310 to 1380 may be provided to the I/O gating circuit 1290 via the data I/O buffer 1295 from the memory controller, and the I/O gating circuit 1290 may write the data DAT in the one bank array through the write drivers.

The control logic circuit 1210 may control operations of the semiconductor memory device 1200. For example, the control logic circuit 1210 may generate control signals for the semiconductor memory device 1200 to perform the write operation and/or the read operation. The control logic circuit 1210 may include a command decoder 1211 that decodes a command CMD received from the memory controller, and a mode register 1212 that sets an operation mode of the semiconductor memory device 1200. In some example embodiments, operations described herein as being performed by the control logic circuit 1210 may be performed by processing circuitry. For example, the command decoder 1211 may generate the control signals corresponding to the command CMD by decoding a write enable signal, a row address strobe signal, a column address strobe signal, a chip selection signal, etc.

The semiconductor memory device 1200 may be the semiconductor memory device according to example embodiments described above with reference to FIGS. 1 through 15. For example, the global bitlines and the local bitline multiplexers may be disposed on both the upper and lower sides of the memory cell array 1300, the structures on the uppermost and lowermost levels of the memory cell array 1300 may be used as the local bitline multiplexers, and different memory cells may be accessed simultaneously through the upper and lower global bitlines. For example, the sense amplifiers SA11, SA12, SA21 and SA22 in FIG. 10 may be included in the sense amplifier unit 1285.

FIG. 17 is a block diagram illustrating a memory system according to example embodiments.

Referring to FIG. 17, a memory system 2000 includes a memory controller 2200 and a semiconductor memory device 2400. The memory system 2000 may further include a plurality of signal lines 2300 that electrically connect the memory controller 2200 with the semiconductor memory device 2400.

The semiconductor memory device 2400 is controlled by the memory controller 2200. For example, based on requests from a host (not illustrated), the memory controller 2200 may store (e.g., write or program) data into the semiconductor memory device 2400, or may retrieve (e.g., read or sense) data from the semiconductor memory device 2400. The semiconductor memory device 2400 may be the memory device according to example embodiments. For example, in the semiconductor memory device 2400, global bitlines TSGBL and local bitline multiplexers TSMUX may be disposed on both the upper and lower sides of the memory cell array, the structures on the uppermost and lowermost levels of the memory cell array may be used as the local bitline multiplexers TSMUX, and different memory cells may be accessed simultaneously through the upper and lower global bitlines TSGBL. Accordingly, the semiconductor memory device 2400 may have improved electrical characteristics and improved reliability.

The plurality of signal lines 2300 may include control lines, command lines, address lines, data input/output (I/O) lines and power lines. The memory controller 2200 may transmit a command CMD, an address ADDR and a control signal CTRL to the semiconductor memory device 2400 via the command lines, the address lines and the control lines, may exchange a data signal DS with the semiconductor memory device 2400 via the data I/O lines, and may transmit a power supply voltage PWR to the semiconductor memory device 2400 via the power lines. Although not illustrated in detail, the plurality of signal lines 2300 may further include data strobe signal (DQS) lines for transmitting a DQS signal.

The example embodiments may be applied to various electronic devices and systems that include the semiconductor memory devices. For example, the example embodiments may be applied to systems such as a personal computer (PC), a server computer, a data center, a workstation, a mobile phone, a smart phone, a tablet computer, a laptop computer, a personal digital assistant (PDA), a portable multimedia player (PMP), a digital camera, a portable game console, a music player, a camcorder, a video player, a navigation device, a wearable device, an internet of things (IOT) device, an internet of everything (IoE) device, an e-book reader, a virtual reality (VR) device, an augmented reality (AR) device, a robotic device, a drone, an automotive, etc.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

The foregoing is illustrative of example embodiments and is not to be construed as limiting thereof. Although some example embodiments have been described, those skilled in the art will readily appreciate that many modifications are possible in the example embodiments without materially departing from the novel teachings and advantages of the example embodiments. Accordingly, all such modifications are intended to be included within the scope of the example embodiments as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A semiconductor memory device comprising:
a plurality of memory cells on a substrate, the plurality of memory cells being arranged along a first direction, a second direction, and a third direction, the first direction being perpendicular to an upper surface of the substrate, the second direction and the third direction being parallel to the upper surface of the substrate and intersecting each other, each of the plurality of memory cells including a cell transistor and a cell capacitor;
a plurality of local bitlines on the substrate, the plurality of local bitlines being connected to the plurality of memory cells, each of the plurality of local bitlines extending in the first direction;
a plurality of wordlines on the substrate, the plurality of wordlines being connected to the plurality of memory cells, each of the plurality of wordlines extending in the third direction;
a plurality of first global bitlines on the plurality of local bitlines;
a plurality of second global bitlines under the plurality of local bitlines;
a plurality of first local bitline multiplexers configured to control electrical connections between the plurality of local bitlines and the plurality of first global bitlines; and
a plurality of second local bitline multiplexers configured to control electrical connections between the plurality of local bitlines and the plurality of second global bitlines,
wherein first memory cells among the plurality of memory cells are different from second memory cells among the plurality of memory cells,
wherein the first memory cells and the second memory cells are configured to be accessed simultaneously by accessing the first memory cells through the plurality of first global bitlines and first local bitlines among the plurality of local bitlines and by accessing the second memory cells through the plurality of second global bitlines and second local bitlines among the plurality of local bitlines, and
the first local bitlines among the plurality of local bitlines are different from the second local bitlines among the plurality of local bitlines.

2. The semiconductor memory device of claim 1,
wherein the plurality of first local bitline multiplexers are on the plurality of memory cells and between the plurality of local bitlines and the plurality of first global bitlines, and
wherein the plurality of second local bitline multiplexers are under the plurality of memory cells and between the plurality of local bitlines and the plurality of second global bitlines.

3. The semiconductor memory device of claim 2, further comprising:
a plurality of first control lines on the plurality of wordlines, each of the plurality of first control lines extending in the third direction, the plurality of first control lines being configured to control turning on and off of the plurality of first local bitline multiplexers; and
a plurality of second control lines under the plurality of wordlines, each of the plurality of second control lines extending in the third direction, the plurality of second control lines being configured to control turning on and off of the plurality of second local bitline multiplexers.

4. The semiconductor memory device of claim 3, wherein
each of the plurality of first local bitline multiplexers includes a first selection transistor connected between one of the plurality of local bitlines and one of the plurality of first global bitlines, and
the first selection transistor includes a gate electrode connected to one of the plurality of first control lines.

5. The semiconductor memory device of claim 4, wherein each of the plurality of first local bitline multiplexers further includes a first dummy capacitor connected to the first selection transistor.

6. The semiconductor memory device of claim 1, further comprising:
a plurality of first contacts between the plurality of first global bitlines and the plurality of first local bitline multiplexers; and
a plurality of second contacts between the plurality of second global bitlines and the plurality of second local bitline multiplexers.

7. The semiconductor memory device of claim 1,
wherein the first memory cells are commonly connected to a first wordline among the plurality of wordlines,
wherein the second memory cells are commonly connected to a second wordline among the plurality of wordlines, and
wherein the first wordline and the second wordline are different from each other.

8. The semiconductor memory device of claim 7, wherein a level of the first wordline in the first direction is different from a level of the second wordline in the first direction.

9. The semiconductor memory device of claim 7,
wherein the first memory cells are adjacent to the plurality of first global bitlines, and
wherein the second memory cells are adjacent to the plurality of second global bitlines.

10. The semiconductor memory device of claim 7,
wherein the first wordline is adjacent to the plurality of first global bitlines, and
wherein the second wordline is adjacent to the plurality of second global bitlines.

11. The semiconductor memory device of claim 1, further comprising:
a plurality of first sense amplifiers connected to the plurality of first global bitlines; and
a plurality of second sense amplifiers connected to the plurality of second global bitlines.

12. The semiconductor memory device of claim 11,
wherein the plurality of memory cells, the plurality of local bitlines, the plurality of wordlines, the plurality of first global bitlines, the plurality of second global bitlines, the plurality of first local bitline multiplexers, and the plurality of second local bitline multiplexers are in a first semiconductor layer,
wherein the plurality of first sense amplifiers are in a second semiconductor layer,
wherein the second semiconductor layer is on the first semiconductor layer, and
wherein the plurality of second sense amplifiers are in a third semiconductor layer under the first semiconductor layer.

13. The semiconductor memory device of claim 1, wherein each of the plurality of local bitlines is shared by memory cells adjacent to a first side of each of the plurality of local bitlines and memory cells adjacent to a second side of each of the plurality of local bitlines, among the plurality of memory cells.

14. A semiconductor memory device comprising:
a first local bitline and a second local bitline on a substrate, the first local bitline and the second local bitline each extending in a first direction, the first direction being perpendicular to an upper surface of the substrate, the first local bitline and the second local bitline being spaced apart from each other in a second direction, the second direction being parallel to the upper surface of the substrate;
first memory cells on the substrate, the first memory cells being arranged along the first direction between the first local bitline and the second local bitline, the first memory cells being connected to the first local bitline, each of the first memory cells including a first cell transistor and a first cell capacitor;
second memory cells on the substrate, the second memory cells being arranged along the first direction between the first local bitline and the second local bitline, the second memory cells being connected to the second local bitline, each of the second memory cells including a second cell transistor and a second cell capacitor;
wordlines on the substrate, the wordlines being connected to the first memory cells and the second memory cells, each of the wordlines extending in a third direction, the third direction being parallel to the upper surface of the substrate and intersecting the second direction;
a first global bitline on the first local bitline and the second local bitline;
a second global bitline under the first local bitline and the second local bitline;
a first local bitline multiplexer and a second local bitline multiplexer on the first memory cells and the second memory cells, respectively,
the first local bitline multiplexer being configured to control an electrical connection between the first local bitline and the first global bitline, and
the second local bitline multiplexer being configured to control an electrical connection between the second local bitline and the first global bitline; and
a third local bitline multiplexer and a fourth local bitline multiplexer under the first memory cells and the second memory cells, respectively,
the third local bitline multiplexer being configured to control an electrical connection between the first local bitline and the second global bitline,
the fourth local bitline multiplexer being configured to control an electrical connection being between the second local bitline and the second global bitline,
wherein a level of a first-first memory cell among the first memory cells is different from a level of a second-first memory cell among the second memory cells, and
wherein the first-first memory cell and the second-first memory cell are configured to be accessed simultaneously by accessing the first-first memory cell through the first global bitline and the first local bitline and by accessing the second-first memory cell through the second global bitline and the second local bitline.

15. The semiconductor memory device of claim 14, wherein
the first local bitline multiplexer includes a first transistor on the first memory cells, and
the first transistor is connected between the first local bitline and the first global bitline.

16. The semiconductor memory device of claim 14,
wherein the first-first memory cell is adjacent to the first global bitline, and
wherein the second-first memory cell is adjacent to the second global bitline.

17. The semiconductor memory device of claim 14, wherein
the wordlines include a first wordline and a second wordline,
the first wordline is connected to the first-first memory cell and adjacent to the first global bitline,
the second wordline is connected to the second-first memory cell and adjacent to the second global bitline, and
a level of the first wordline is different from a level of the second wordline.

18. The semiconductor memory device of claim 14, further comprising:
a first sense amplifier connected to the first global bitline; and
a second sense amplifier connected to the second global bitline.

19. The semiconductor memory device of claim 18, wherein
the first local bitline, the second local bitline, the first memory cells, the second memory cells, the wordlines, the first global bitline, the second global bitline, the first local bitline multiplexer, the second local bitline multiplexer, the third local bitline multiplexer, and the fourth local bitline multiplexer are in a first semiconductor layer,
the first sense amplifier and the second sense amplifier are in an other semiconductor layer, and
the other semiconductor layer is on the first semiconductor layer or the other semiconductor layer is under the first semiconductor layer.

20. A memory system comprising:
a memory controller; and
a semiconductor memory device, wherein
the memory controller is configured to control the semiconductor memory device, and
the semiconductor memory device includes:
a plurality of memory cells on a substrate, the plurality of memory cells being arranged along a first direction, a second direction and a third direction,
the first direction being perpendicular to an upper surface of the substrate,
the second direction and the third direction being parallel to the upper surface of the substrate and intersecting each other, each of the plurality of memory cells including a cell transistor and a cell capacitor;
a plurality of local bitlines on the substrate, the plurality of local bitlines being connected to the plurality of memory cells, each of the plurality of local bitlines extending in the first direction;
a plurality of wordlines on the substrate, the plurality of wordlines being connected to the plurality of memory cells, each of the plurality of wordlines extending in the third direction;
a plurality of first global bitlines on the plurality of local bitlines;
a plurality of second global bitlines under the plurality of local bitlines;
a plurality of first local bitline multiplexers configured to control electrical connections between the plurality of local bitlines and the plurality of first global bitlines; and
a plurality of second local bitline multiplexers configured to control electrical connections between the plurality of local bitlines and the plurality of second global bitlines,
wherein first memory cells among the plurality of memory cells are different from second memory cells among the plurality of memory cells,
wherein the first memory cells and the second memory cells are configured to be accessed simultaneously by accessing the first memory cells through the plurality of first global bitlines and first local bitlines among the plurality of local bitlines and by accessing the second memory cells through the plurality of second global bitlines and second local bitlines among the plurality of local bitlines, and
wherein the first local bitlines among the plurality of local bitlines are different from the second local bitlines among the plurality of local bitlines.
